(19) United States
(12) Patent Application Publication
(10) Pub. No.: US 2025/0239209 A1
(43) Pub. Date: Jul. 24, 2025

(54) DISPLAY DEVICE

(71) Applicant: LG Display Co., Ltd., Seoul (KR)

(72) Inventor: Haksu KIM, Paju-si (KR)

(73) Assignee: LG Display Co., Ltd., Seoul (KR)

(21) Appl. No.: 18/825,859

(22) Filed: Sep. 5, 2024

(30) Foreign Application Priority Data
Jan. 22, 2024 (KR) 10-2024-0009708

(51) Int. Cl. G09G 3/32

(52) U.S. Cl. CPC G09G 3/32; G09G 2310/08; G09G 2320/028; G09G 2320/068; G09G 2380/10

(57) ABSTRACT

A display device can include a display panel having an active area and a non-active area and having a plurality of pixels and a plurality of selection signal generators disposed on the active area, and a timing controller configured to control the display panel. Each pixel can include a first light emitting element, a first optical member configured to refract light from the first light emitting element, a second light emitting element configured to emit light of the same color as the first light emitting element, and a second optical member configured to refract the light from the second light emitting element and having a different shape from the first optical member. Each selection signal generator can control one of the first light emitting element and the second light emitting element included in at least one corresponding pixel among the pixels to emit light.

### CROSS-REFERENCE TO RELATED APPLICATIONS

This application claims priority to Korean Patent Application No. 10-2024-0009708 filed on Jan. 22, 2024, in the Korean Intellectual Property Office, the entire contents of which is hereby expressly incorporated by reference into the present application.

### BACKGROUND

### Field

The present disclosure relates to a display device, and more particularly, to a display device capable of controlling a viewing angle.

### Discussion of the Related Art

In accordance with the development of technology in modern society, a display device is being used in various ways to provide information to users. The display device is included not only in an electronic signboard that simply transmits visual information in one direction, but also in various electronic devices that need higher technology to confirm user input and provide information in response to the confirmed input.

For example, the display device can be included in a vehicle to provide various types of information to a driver and passengers of the vehicle. However, the display device of the vehicle needs to display content appropriately so as not to interfere with the operation of the vehicle. For example, the display device needs to limit the display of content that can reduce concentration on driving while the vehicle is in operation.

### SUMMARY OF THE DISCLOSURE

An object to be achieved by the present disclosure is to provide a display device capable of independently controlling driving modes of each area by dividing a display panel by area.

Another object to be achieved by the present disclosure is to provide a display device capable of minimizing the number of lines and a pixel layout disposed on a display panel.

Still another object to be achieved by the present disclosure is to provide a display device capable of implementing high resolution.

Objects of the present disclosure are not limited to the above-mentioned objects, and other objects, which are not mentioned above, can be clearly understood by those skilled in the art from the following descriptions.

According to an aspect of the present disclosure, a display device can include a display panel including an active area and a non-active area surrounding the active area, and including a plurality of pixels and a plurality of selection signal generators disposed on the active area; and a timing controller configured to control the display panel. Each of the plurality of pixels can include a first light emitting element, a first optical member configured to refract light from the first light emitting element, a second light emitting element configured to emit light of the same color as the first light emitting element, and a second optical member configured to refract the light from the second light emitting element and having a different shape from the first optical member. Each of the plurality of selection signal generators can control one of the first light emitting element and the second light emitting element included in at least one corresponding pixel among the plurality of pixels to emit light.

Other detailed matters of the example embodiments are included in the detailed description and the drawings.

According to an example embodiment of the present disclosure, by independently controlling driving modes of each area by dividing a display panel by area, it is possible to drive each area in a first mode that provides content with a wide viewing angle or in a second mode that provides content with a narrow viewing angle.

According to an example embodiment of the present disclosure, by independently controlling driving modes of each area by dividing a display panel by area without increasing the number of lines and pixel layout disposed on the display panel, it is possible to implement the display panel with high resolution.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an example diagram of a display device according to an example embodiment of the present disclosure;

FIG. 2 is a functional block diagram of the display device according to an example embodiment of the present disclosure;

FIGS. 3A to 3E are diagrams illustrating examples of a display panel included in the display device of FIG. 2;

FIG. 4 is a circuit diagram illustrating an example of a pixel circuit included in the display device of FIG. 2;

FIGS. 5A and 5B are waveform diagrams for describing the pixel circuit of FIG. 4;

FIGS. 6 and 7 are cross-sectional views of a portion of the display device according to the example embodiment of the present disclosure;

FIG. 8 is a circuit diagram illustrating an example of a selection signal generation circuit included in the display device of FIG. 2;

FIG. 9 is a diagram for describing an example of an operation of the selection signal generation circuit of FIG. 8;

FIGS. 10A to 10D are equivalent circuit diagrams for describing an example of the operation of the selection signal generation circuit of FIG. 8;

FIG. 11 is a circuit diagram illustrating another example of the pixel circuit included in the display device of FIG. 2;

FIG. 12 is a circuit diagram illustrating another example of the selection signal generation circuit included in the display device of FIG. 2;

FIG. 13 is a diagram for describing an example of the operation of the selection signal generation circuit of FIG. 12;

FIGS. 14A to 14D are equivalent circuit diagrams for describing an example of the operation of the selection signal generation circuit of FIG. 12;

FIG. 15 is a circuit diagram illustrating another example of the selection signal generation circuit included in the display device of FIG. 2;

FIG. 16 is a diagram for describing an example of the operation of the selection signal generation circuit of FIG. 15; and

FIGS. 17A to 17D are equivalent circuit diagrams for describing an example of the operation of the selection signal generation circuit of FIG. 15.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “over”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” encompasses all the meanings and coverages of the term “may.”

Hereinafter, a display device according to example embodiments of the present disclosure will be described in detail with reference to accompanying drawings. All the components of each display device according to all embodiments of the present disclosure are operatively coupled and configured.

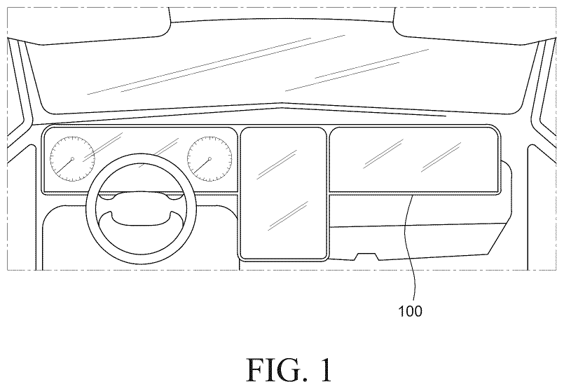

FIG. 1 is an example diagram of a display device according to an example embodiment of the present disclosure.

Referring to FIG. 1, a display device 100 can be disposed on at least a portion of a dashboard of a vehicle. The dashboard of the vehicle can include components disposed in front of front seats (e.g., driver's seat, passenger seat) of the vehicle. For example, the dashboard of the vehicle can have input configurations for operating various functions (e.g., air conditioning, audio system, navigation system) inside the vehicle.

The display device 100 can operate as an input unit that is disposed on the dashboard of the vehicle and manipulates at least some of various functions of the vehicle. In the display device 100, various information related to the vehicle, such as vehicle operation information (e.g., vehicle current speed, remaining fuel amount, driving distance), information (e.g., damage to vehicle tires) on vehicle parts, etc., can be provided.

The display device 100 can be disposed to cross the driver's seat and passenger seat disposed on the front seats of the vehicle. A user of the display device 100 can include a driver of the vehicle and a passenger riding in the passenger seat. Both the driver and passenger of the vehicle can use the display device 100.

The display device 100 can represent a display panel among various components included in the display device 100. Specifically, for example, the display device 100 illustrated in FIG. 1 can represent at least a portion of an active area and a non-active area of the display panel. Among the components of the display device 100, components other than those illustrated in FIG. 1 can be mounted inside (or in at least part of) the vehicle.

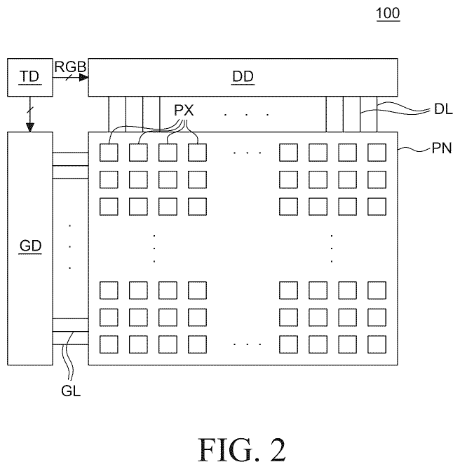

FIG. 2 is a functional block diagram of the display device according to an example embodiment of the present disclosure.

As the display device according to an example embodiment of the present disclosure, an electroluminescent display device can be applied. As the electroluminescent display device, an organic light emitting diode display device, a quantum-dot light emitting diode display device, or an inorganic light emitting diode display device can be used.

Referring to FIG. 2, the display device 100 can include a display panel PN, a data driving circuit DD, a gate driving circuit GD, and a timing controller TD.

The display panel PN can generate an image to be provided to a user. For example, the display panel PN can generate and display an image to be provided to a user through a plurality of pixels PX, each of which has a pixel circuit disposed.

The data driving circuit DD, the gate driving circuit GD, and the timing controller TD can provide signals for the operation of each pixel PX through signal lines. For example, the signal lines configured to provide signals for the operation of each pixel PX can include a plurality of data lines DL and a plurality of gates line GL.

The plurality of data lines DL can include a plurality of lines that is disposed in a column direction and connected to the pixel PX disposed in one column direction, and the plurality of gate lines GL can include a plurality of lines that is disposed in a row direction and connected to pixels PX disposed in one row direction.

In some cases, the display device 100 can further include a power supply unit. In this case, a signal for operating the pixel PX can be provided through a power line connecting the power supply unit and the display panel PN. According to an example embodiment, the power supply unit can provide power to the data driving circuit DD and the gate driving circuit GD. The data driving circuit DD and the gate driving circuit GD can be driven based on power provided from the power supply unit.

For example, the data driving circuit DD can apply a data signal to each pixel PX through the plurality of data lines DL, the gate driving circuit GD can apply a gate signal to each pixel PX through the plurality of gate lines GL, and the power supply unit can supply power voltage to each pixel PX through power voltage supply lines.

The timing controller TD can control the data driving circuit DD and the gate driving circuit GD. For example, the timing controller TD can rearrange digital video data input from the outside to match a resolution of the display panel PN and supply the rearranged digital video data to the data driving circuit DD.

The data driving circuit DD can convert the digital video data input from the timing controller TD into an analog data voltage based on a data control signal and supply the analog data voltage to the plurality of data lines DL.

The gate driving circuit GD can generate a scan signal and an emission signal based on a gate control signal. For example, the gate driving circuit GD can include a scan driver and a light emission signal driver. The scan driver can generate scan signals in a row sequential manner to drive at least one scan line connected to each pixel row and supply the generated scan signals to the scan lines. The light emission signal driver can generate the emission signal in the row sequential manner to drive at least one emission signal line connected to each pixel row and supply the generated emission signal to the emission signal lines.

According to an example embodiment, the gate driving circuit GD can be disposed on the display panel PN using a gate-driver in panel (GIP) manner. For example, the gate driving circuit GD can be divided into plurality and disposed on at least two side surfaces of the display panel PN, respectively.

The display panel PN can include an active area and a non-active area surrounding the active area.

The active area of the display panel PN can include a plurality of pixels PX disposed in the row and column directions. For example, the plurality of pixels PX can be disposed in an area where the plurality of data lines DL and the plurality of gate lines GL intersect.

One pixel PX can include a plurality of sub-pixels that emits different colors. For example, one pixel PX can implement blue, red, and green colors using three sub-pixels. However, the pixel PX is not limited thereto, and in some cases, the pixel PX can further include sub-pixels to further implement a specific color such as white.

In the pixel PX, an area implementing blue can be referred to as a blue sub-pixel, an area implementing red can be referred to as a red sub-pixel, and an area implementing green can be referred to as a green sub-pixel.

Each of the plurality of pixels PX can include a first light emitting element and a second light emitting element that emit the same color.

Each of the plurality of pixels PX can include a first optical member that refracts light from the first light emitting element in a specific direction and a second optical member that refracts light from the second light emitting element in a specific direction. For example, the first optical member and the second optical member can each be implemented as a lens, but the example embodiment of the present disclosure is not limited thereto.

For example, the first optical member is disposed in an optical area that provides light in a first range to form a first viewing angle, and the second optical member is disposed in an optical area that provides light in a second range to form a second viewing angle. The first range can correspond to a wider range than the second range. Accordingly, the first optical member and the second optical member can limit viewing angles of each of the plurality of pixels PX.

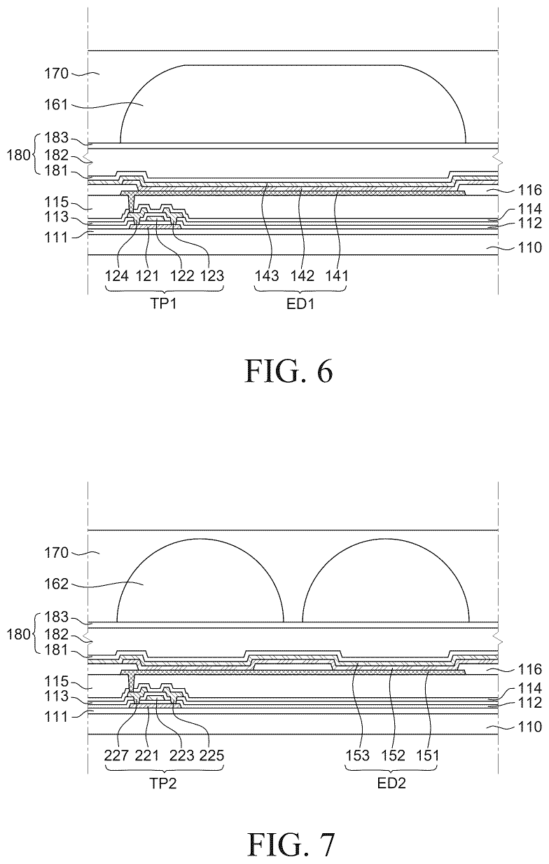

A detailed description of the first optical member and the second optical member will be described below with reference to FIGS. 6 and 7.

The non-active area can be disposed along a circumference of the active area. Various components for driving the sub-pixels disposed in the pixel PX can be disposed in the non-active area. For example, at least a portion of the gate driving circuit GD can be disposed in the non-active area. The non-active area can be referred to as a bezel area.

When the display panel PN is used in the vehicle described with reference to FIG. 1, the field of view of at least some areas of the display panel PN needs to be limited depending on the user's needs. For example, in the case of images displayed in an area, which provides entertainment functions, seat information, etc., for passengers sitting in the passenger seat, in the active area of the display panel PN, the images can interfere with the driver's driving of the vehicle, so it can be necessary to limit the field of view of the image displayed in the area depending on the user's needs.

Accordingly, depending on the driving mode, each pixel PX included in the display panel PN can be driven in a first mode or a second mode. For example, when the pixel PX is driven in the first mode, the first light emitting element included in the pixel PX emits light based on the selection signal to provide the light from the first light emitting element to the first range through the first optical member, thereby forming the first viewing angle, for example, the wide viewing angle. In addition, when the pixel PX is driven in the second mode, the second light emitting element included in the pixel PX emits light based on the selection signal to provide the light from the second light emitting element to the second range through the second optical member, thereby forming the second viewing angle, for example, the narrow viewing angle. Here, the first mode can correspond to a mode in which the corresponding pixel PX is controlled in a share mode, and the second mode can correspond to a mode in which the corresponding pixel PX is driven in a private mode.

Meanwhile, when controlling the driving mode, it is necessary to independently control the driving modes of each area by dividing the display panel PN by area. In this case, when the selection signal for controlling the driving mode of the pixels PX disposed in each area is generated from a driving circuit such as a D-IC (driving integrated circuit) and provided to the pixel PX in the corresponding area, the selection signal line can be disposed throughout the display panel PN to provide the selection signal from the driving circuit to the pixels PX in the corresponding area, so the number of divided areas can be limited. For example, as the number of divided areas increases, the number of selection signal lines disposed throughout the display panel PN increases, which can cause a problem in that the number of lines disposed throughout the display panel PN and the area occupied by the lines increase. In addition, when the pixel circuit changes to receive selection signals in a matrix form within each pixel PX in order to reduce the number of selection signal lines, transistors within the pixel PX can be added and thus a pixel layout can be complicated, making it difficult to implement high resolution.

Accordingly, the display device 100 according to an example embodiment of the present disclosure can further include at least one selection signal generator for controlling the driving mode of the pixel PX in the corresponding area for each divided area. The selection signal generator can be disposed on the display panel PN, and one selection signal generator can be disposed to commonly control the driving mode of the pixels PX disposed in the corresponding area by area.

The selection signal generator can control the driving mode of the pixel PX. For example, the selection signal generator can generate a selection signal and provide the generated selection signal to the pixel PX. As described above, the pixel PX can be driven in the first mode or the second mode based on the selection signal.

In this way, the selection signal generator for controlling the driving mode of the pixel PX can be disposed on the display panel PN. For example, the selection signal generator can be disposed in an area of the active area of the display panel PN where the pixel PX is not disposed, and/or can be disposed on a different layer from components included in the pixel PX. Accordingly, as described above, it is possible to independently control the driving modes of each area by dividing the display panel PN by area without increasing the number of selection signal lines connected from the driving circuit to the pixel PX or changing the pixel circuit. Therefore, by independently controlling the driving modes of each area by dividing the display panel PN by area, it is possible to minimize the number of lines and pixel layout disposed on the display panel PN and to implement the high resolution.

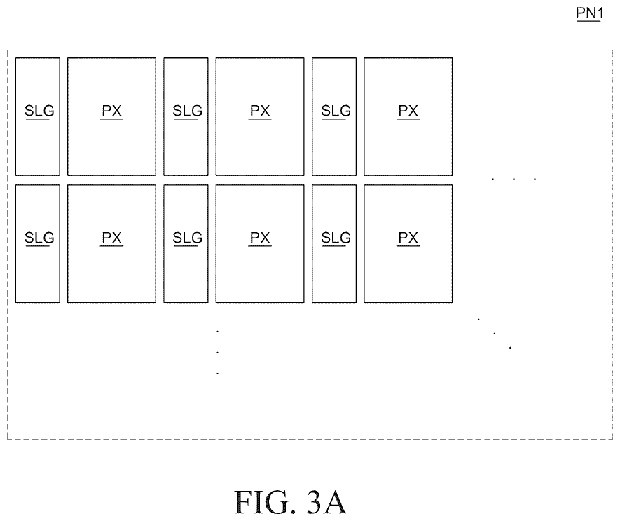

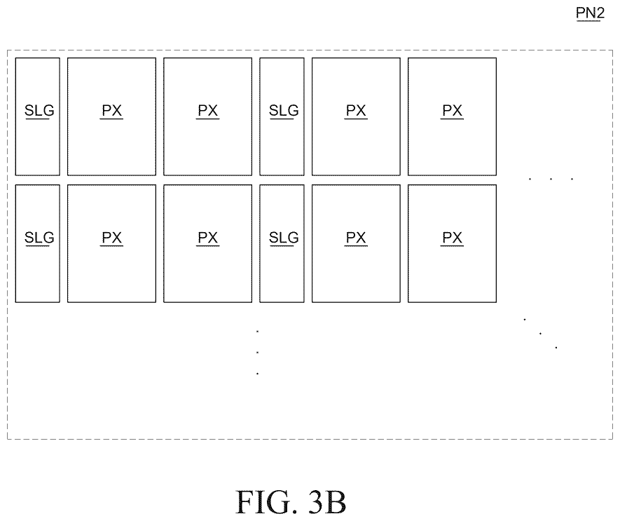

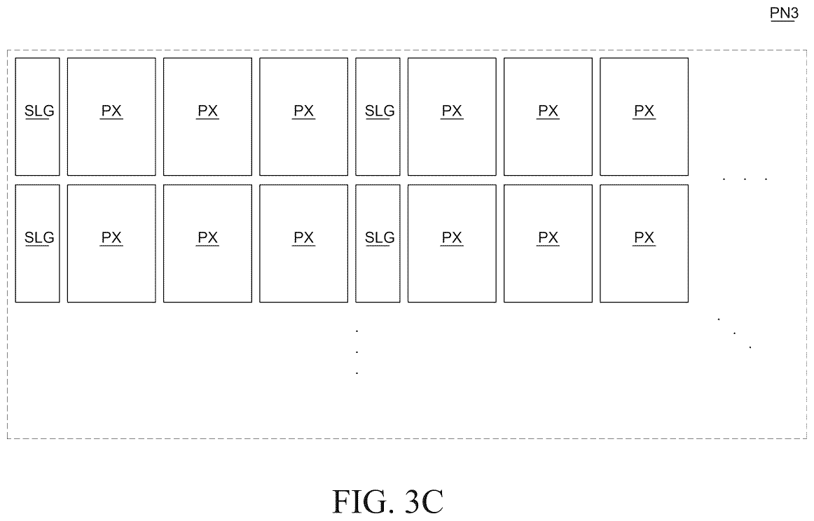

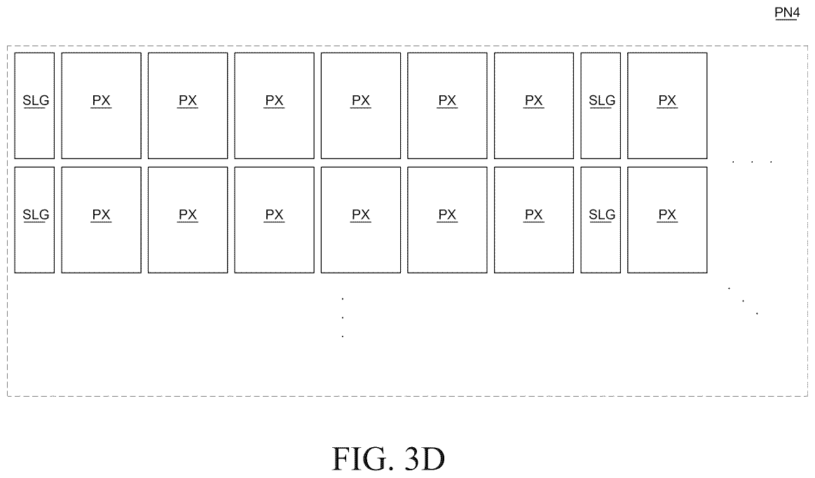

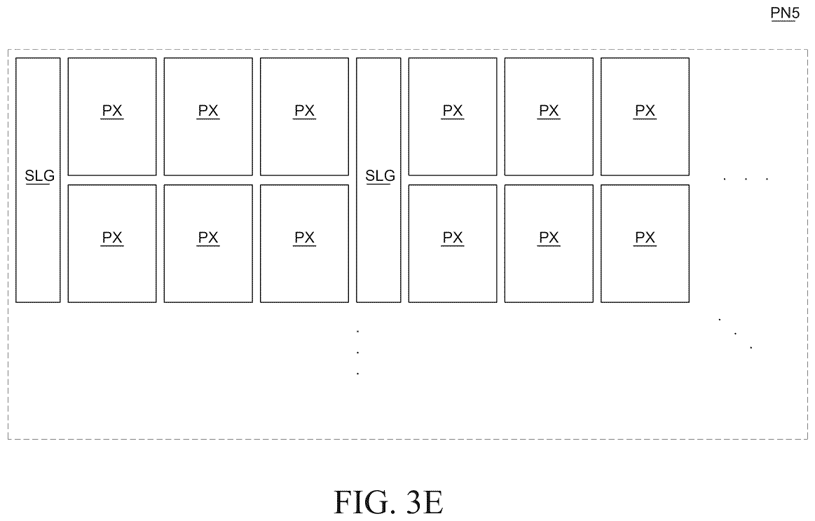

A detailed description of the selection signal generator will be described below with reference to FIGS. 3A to 3E, 8 to 10D, and 12 to 17D.

FIGS. 3A to 3E are diagrams illustrating examples of the display panel included in the display device of FIG. 2.

Meanwhile, a first display panel PN1, a second display panel PN2, a third display panel PN3, a fourth display panel PN4, and a fifth display panel PN5 illustrated in FIGS. 3A to 3E each represent various example embodiments of the display panel PN described with reference to FIG. 2.

Referring to FIG. 3A, the first display panel PN1 can include a plurality of selection signal generators SLG and the plurality of pixels PX.

Each of the plurality of selection signal generators SLG can be disposed for each pixel PX to control the driving mode of the corresponding pixel PX. For example, as illustrated in FIG. 3A, each of the plurality of selection signal generators SLG can be disposed on one side of each pixel PX. For example, the selection signal generator SLG and the pixel PX can be disposed on the first display panel PN1 in a 1:1 ratio.

Each of the plurality of selection signal generators SLG can provide the selection signal to the corresponding one pixel PX to control the driving mode of the corresponding pixel PX. Accordingly, the driving modes can be independently controlled for each pixel PX included in the first display panel PN1. For example, the first display panel PN1 includes a plurality of areas defined in units of one pixel PX, and the driving modes of the plurality of corresponding areas can be independently controlled. For example, in the case of the plurality of pixels PX included in the first display panel PN1, the driving mode can be independently controlled for each individual pixel PX. Meanwhile, in this case, one selection signal generator SLG and one pixel PX corresponding thereto can be defined as a pixel block or pixel unit.

Referring to FIG. 3B, the second display panel PN2 can include the plurality of selection signal generators SLG and the plurality of pixels PX.

Each of the plurality of selection signal generators SLG can be disposed for each two pixels PX to control the driving modes of the corresponding two pixels PX. For example, as illustrated in FIG. 3B, each of the plurality of selection signal generators SLG can be disposed on one side along a row direction of any one of the two pixels PX disposed in the row direction. For example, the selection signal generator SLG and the pixel PX can be disposed on the second display panel PN2 in a 1:2 ratio. However, the present disclosure is not limited thereto, and each of the plurality of selection signal generators SLG can be disposed on one side along a column direction of any one of the two pixels PX disposed in the column direction.

Each of the plurality of selection signal generators SLG can provide the selection signal to the corresponding two pixels PX to commonly control the driving modes of the corresponding two pixels PX. Accordingly, the driving modes can be independently controlled for each two pixels PX included in the second display panel PN2. For example, the second display panel PN2 includes a plurality of areas defined in units of two pixels PX, and the driving modes of the plurality of corresponding areas can be independently controlled. For example, in the case of the plurality of pixels PX included in the second display panel PN2, the driving modes can be independently controlled for each two pixels PX. Meanwhile, in this case, one selection signal generator SLG and two pixels PX corresponding thereto can be defined as a pixel block or pixel unit.

Referring to FIG. 3C, the third display panel PN3 can include the plurality of selection signal generators SLG and the plurality of pixels PX.

Each of the plurality of selection signal generators SLG can be disposed for each three pixels PX to control the driving modes of the corresponding three pixels PX. For example, as illustrated in FIG. 3C, each of the plurality of selection signal generators SLG can be disposed on one side along a row direction of any one of the three pixels PX disposed in the row direction. For example, the selection signal generator SLG and the pixel PX can be disposed on the third display panel PN3 in a 1:3 ratio. However, the present disclosure is not limited thereto, and each of the plurality of selection signal generators SLG can be disposed on one side along a column direction of any one of the three pixels PX disposed in the column direction.

Each of the plurality of selection signal generators SLG can provide the selection signal to the corresponding three pixels PX to commonly control the driving modes of the corresponding three pixels PX. Accordingly, the driving modes can be independently controlled for each three pixels PX included in the third display panel PN3. For example, the third display panel PN3 includes a plurality of areas defined in units of three pixels PX, and the driving modes of the plurality of corresponding areas can be independently controlled. For example, in the case of the plurality of pixels PX included in the third display panel PN3, the driving modes can be independently controlled for each three pixels PX. Meanwhile, in this case, one selection signal generator SLG and three pixels PX corresponding thereto can be defined as a pixel block or pixel unit.

Referring to FIG. 3D, the fourth display panel PN4 can include the plurality of selection signal generators SLG and the plurality of pixels PX.

Each of the plurality of selection signal generators SLG can be disposed for each six pixels PX to control the driving modes of the corresponding six pixels PX. For example, as illustrated in FIG. 3D, each of the plurality of selection signal generators SLG can be disposed on one side along a row direction of any one of the six pixels PX disposed in the row direction. For example, the selection signal generator SLG and the pixel PX can be disposed on the fourth display panel PN4 in a 1:6 ratio. However, the present disclosure is not limited thereto, and each of the plurality of selection signal generators SLG can be disposed on one side along a column direction of any one of the six pixels PX disposed in the column direction.

Each of the plurality of selection signal generators SLG can provide the selection signal to the corresponding six pixels PX to commonly control the driving modes of the corresponding six pixels PX. Accordingly, the driving modes can be independently controlled for each six pixels PX included in the fourth display panel PN4. For example, the fourth display panel PN4 includes a plurality of areas defined in units of six pixels PX, and the driving modes of the plurality of corresponding areas can be independently controlled. For example, in the case of the plurality of pixels PX included in the fourth display panel PN4, the driving modes can be independently controlled for each six pixels PX. Meanwhile, in this case, one selection signal generator SLG and six pixels PX corresponding thereto can be defined as a pixel block or pixel unit.

Referring to FIG. 3E, the fifth display panel PN5 can include the plurality of selection signal generators SLG and the plurality of pixels PX.

Each of the plurality of selection signal generators SLG can be disposed for each six pixels PX to control the driving modes of the corresponding six pixels PX. For example, as illustrated in FIG. 3E, each of the plurality of selection signal generators SLG can be disposed on one side along a row direction of two pixel PX disposed in the same column among six pixels PX disposed three in each of the two rows. For example, the selection signal generator SLG and the pixel PX can be disposed on the fifth display panel PN5 in a 1:6 ratio. However, the present disclosure is not limited thereto, and each of the plurality of selection signal generators SLG can be disposed on one side along a column direction of the two pixels PX disposed in the same row among the six pixels PX disposed three in each of two columns.

Each of the plurality of selection signal generators SLG can provide the selection signal to the corresponding six pixels PX to commonly control the driving modes of the corresponding six pixels PX. Accordingly, the driving modes can be independently controlled for each six pixels PX included in the fifth display panel PN5. For example, the fifth display panel PN5 includes a plurality of areas defined in units of six pixels PX, and the driving modes of the plurality of corresponding areas can be independently controlled. For example, in the case of the plurality of pixels PX included in the fifth display panel PN5, the driving modes can be independently controlled for each six pixels PX.

As such, the disposition relationship between the selection signal generator SLG and the pixel PX included in the display panel PN of the display device 100 according to an example embodiment of the present disclosure can be designed in various ways. Here, as described above, the area of the display panel PN is divided for each pixel PX that is commonly controlled by one selection signal generator SLG, so the driving modes can be controlled independently for each area. Accordingly, the display panel PN can be divided into various areas according to the design of the display device 100, so the corresponding areas can be controlled independently. Meanwhile, in this case, one selection signal generator SLG and six pixels PX corresponding thereto can be defined as a pixel block or pixel unit.

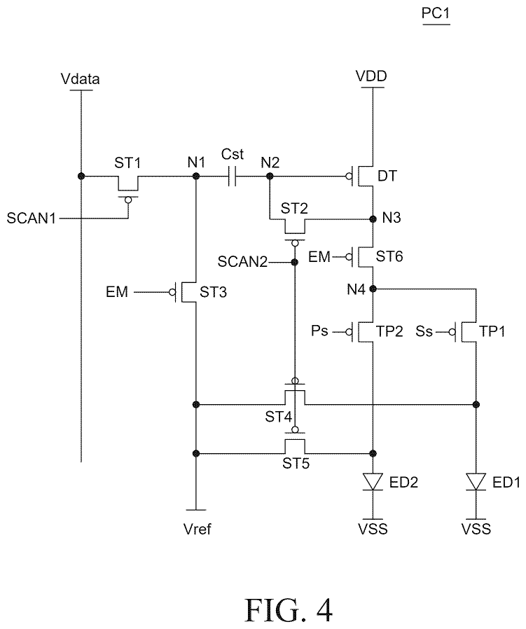

FIG. 4 is a circuit diagram illustrating an example of the pixel circuit included in the display device of FIG. 2.

Meanwhile, a first pixel circuit PC1 illustrated in FIG. 4 represents an example embodiment of pixel circuits corresponding to each of the plurality of pixels PX included in the display device 100 described with reference to FIG. 2.

Referring to FIG. 4, at least some of the plurality of transistors included in the first pixel circuit PC1 can be n-type transistors or p-type transistors. In the case of the p-type transistor, a low-level voltage of each driving signal refers to a voltage that turns on a TFT, and a high-level voltage of each driving signal can refer to a voltage that turns off TFTs.

Here, the low-level voltage can correspond to a preset voltage that is lower than the high level. For example, the low-level voltage can include a voltage that falls within the range of −8 V to −12 V. The high-level voltage can correspond to a preset voltage that is higher than the low-level voltage. For example, the high-level voltage can include a voltage that falls within the range of 12 V to 16 V. According to an example embodiment, the low-level voltage can be referred to as a first voltage, and the high-level voltage can be referred to as a second voltage. In this case, the first voltage can be lower than the second voltage.

The first pixel circuit PC1 can include a driving transistor DT, a plurality of switching transistors ST1 to ST6, a plurality of selection transistors TP1 and TP2, a storage capacitor Cst, and a plurality of light emitting elements ED1 and ED2.

The driving transistor DT can control a driving current applied to the plurality of light emitting elements ED1 and ED2 according to a source-gate voltage. The driving transistor DT can include a source electrode connected to a high-potential power line to which a high-potential power voltage VDD is supplied, a gate electrode connected to a second node N2, and a drain electrode connected to a third node N3.

The first switching transistor ST1 can apply a data voltage Vdata from the data line DL to the first node N1. The first switching transistor ST1 can include a source electrode connected to the data line DL, the drain electrode connected to the first node N1, and a gate electrode connected to a first scan signal line to which a first scan signal SCAN1 is applied. The first switching transistor ST1 can be turned on or off by the first scan signal SCAN1. Accordingly, the first switching transistor ST1 can apply the data voltage Vdata from the data line DL to the first node N1 in response to the first scan signal SCAN1 having a low level which is a turn-on level.

The second switching transistor ST2 can diode-connect the gate electrode and drain electrode of the driving transistor DT. The second switching transistor ST2 can include a drain electrode connected to the second node N2, a source electrode connected to the third node N3, and a gate electrode connected to a second scan signal line to which a second scan signal SCAN2 is applied. The second switching transistor ST2 can be turned on or off by the second scan signal SCAN2. Accordingly, the second switching transistor ST2 can diode-connect the gate electrode and drain electrode of the driving transistor DT in response to the second scan signal SCAN2 having the low level which is the turn-on level.

The third switching transistor ST3 can apply a reference voltage Vref to the first node N1. The third switching transistor ST3 can include a source electrode connected to a reference voltage line configured to provide the reference voltage Vref, a drain electrode connected to the first node N1, and a gate electrode connected to an emission signal line to which an emission signal EM is applied. The third switching transistor ST3 can be turned on or off by the emission signal EM. Accordingly, the third switching transistor ST3 can transmit the reference voltage Vref to the first node N1 in response to an emission signal EM having the low level which is the turn-on level.

The fourth switching transistor ST4 can apply the reference voltage Vref to an anode electrode of the first light emitting element ED1. The fourth switching transistor ST4 can include a source electrode connected to the reference voltage line configured to provide the reference voltage Vref, a drain electrode connected to the anode electrode of the first light emitting element ED1, and a gate electrode connected to the second scan signal line to which the second scan signal SCAN2 is applied. The fourth switching transistor ST4 can be turned on or off by the second scan signal SCAN2. Accordingly, the fourth switching transistor ST4 can apply the reference voltage Vref to the anode electrode of the first light emitting element ED1 in response to the second scan signal SCAN2 having the low level which is the turn-on level.

The fifth switching transistor ST5 can apply the reference voltage Vref to an anode electrode of the second light emitting element ED2. The fifth switching transistor ST5 can include a source electrode connected to the reference voltage line configured to provide the reference voltage Vref, a drain electrode connected to the anode electrode of the second light emitting element ED2, and a gate electrode connected to the second scan signal line to which the second scan signal SCAN2 is applied. The fifth switching transistor ST5 can be turned on or off by the second scan signal SCAN2. Accordingly, the fifth switching transistor ST5 can apply the reference voltage Vref to the anode electrode of the second light emitting element ED2 in response to the second scan signal SCAN2 having the low level which is the turn-on level.

The sixth switching transistor ST6 can form a current path between the driving transistor DT and any one of the plurality of light emitting elements ED1 and ED2. The sixth switching transistor ST6 can include a source electrode connected to the third node N3, a drain electrode connected to the fourth node N4, and a gate electrode connected to the emission signal line to which the emission signal EM is applied. The sixth switching transistor ST6 can be turned on or off by the emission signal EM. Accordingly, the sixth switching transistor ST6 can electrically connect the third node N3 and the fourth node N4 in response to the emission signal EM having the low level, which is the turn-on level, to form a current path between the driving transistor DT and any one of the plurality of light emitting elements ED1 and ED2.

The storage capacitor Cst can include a first electrode connected to the first node N1 and a second electrode connected to the second node N2. One electrode of the storage capacitor Cst can be connected to the gate electrode of the driving transistor DT, and the other electrode of the storage capacitor Cst can be connected to the first switching transistor ST1. The storage capacitor Cst can store a certain voltage and keep the voltage of the gate electrode of the driving transistor DT constant while any of the plurality of light emitting elements ED1 and ED2 emits light.

The plurality of selection transistors TP1 and TP2 can include a first selection transistor TP1 configured to generate a current path of a first driving current passing through the first light emitting element ED1 and a second selection transistor TP2 configured to generate a current path of a second driving current passing through the second light emitting element ED2.

The first selection transistor TP1 can be connected between the fourth node N4 and the first light emitting element ED1, and the gate electrode of the first selection transistor TP1 can be connected to a first selection signal line that provides a first selection signal Ss. When the pixel PX to which the first pixel circuit PC1 is applied is driven in a first mode which is the share mode, the first selection signal Ss is supplied to the gate electrode of the first selection transistor TP1, so the first selection transistor TP1 can be turned on. Accordingly, the current path of the first driving current passing through the first light emitting element ED1 can be formed, so the first light emitting element ED1 can emit light. Meanwhile, the first selection transistor TP1 can also be referred to as a first emission control transistor that controls the emission of the first light emitting element ED1.

The second selection transistor TP2 can be connected between the fourth node N4 and the second light emitting element ED2, and the gate electrode of the second selection transistor TP2 can be connected to a second selection signal line that provides a second selection signal Ps. When the pixel PX to which the first pixel circuit PC1 is applied is driven in a second mode which is the private mode, the second selection signal Ps is supplied to the gate electrode of the second selection transistor TP2, so the second selection transistor TP2 can be turned on. Accordingly, the current path of the second driving current passing through the second light emitting element ED2 can be formed, so the second light emitting element ED2 can emit light. Meanwhile, the second selection transistor TP2 can also be referred to as a second emission control transistor that controls the emission of the second light emitting element ED2.

The first light emitting element ED1 can be connected between the first selection transistor TP1, which is turned on or off by the first selection signal Ss, and a low-potential power line that provides a low-potential power voltage VSS. The second light emitting element ED2 can be connected between the second selection transistor TP2, which is turned on or off by the second selection signal Ps, and the low-potential power line that provides the low-potential power voltage VSS.

In this case, the first light emitting element ED1 or the second light emitting element ED2 can be connected to other components (e.g., driving transistor DT) of the first pixel circuit PC1 by the first selection transistor TP1 or the second selection transistor TP2 turned on according to the driving mode. For example, the first light emitting element ED1 can be connected to the driving transistor DT via the first selection transistor TP1 turned on in the first mode, and can provide light at the wide-viewing angle, which is the first viewing angle, in the first mode (i.e., share mode), by the first driving current. In addition, the second light emitting element ED2 can be connected to the driving transistor DT via the second selection transistor TP2 turned on in the second mode, and can provide light at the narrow-viewing angle, which is the second viewing angle, in the second mode (i.e., private mode), by the second driving current. Here, the driving mode can be specified by user input or determined when pre-specified conditions are met.

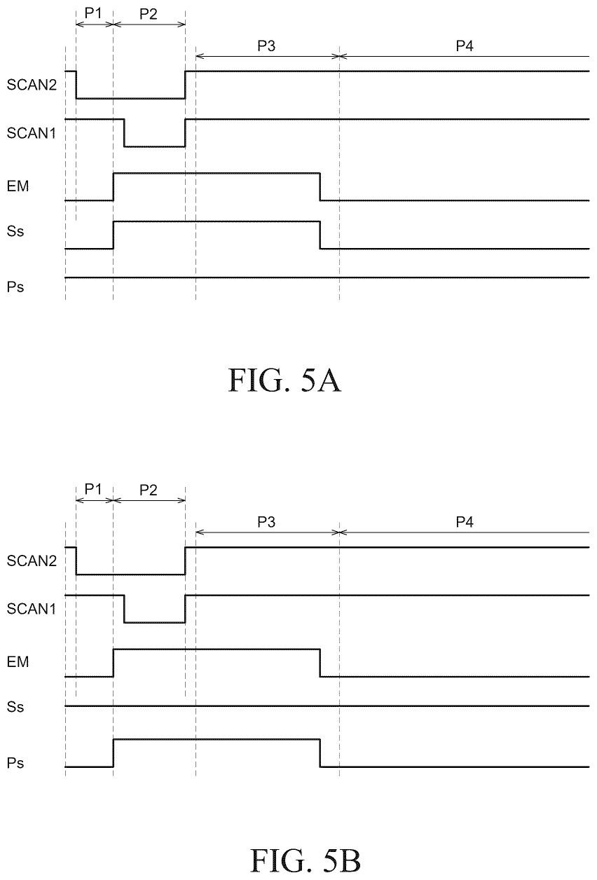

FIGS. 5A and 5B are waveform diagrams for describing the pixel circuit of FIG. 4.

Particularly, FIG. 5A illustrates a waveform diagram for describing an example when the pixel PX to which the first pixel circuit PC1 is applied is driven in the first mode, and FIG. 5B illustrates a waveform diagram for describing an example when the pixel PX to which the first pixel circuit PC1 is applied is driven in the second mode.

Referring to FIGS. 4 to 5B, in the first mode, only the first light emitting element ED1 can emit light, and in the second mode, only the second light emitting element ED2 can emit light. Here, as illustrated in FIG. 5A, the second selection signal Ps for controlling the emission of the second light emitting element ED2 so that only the first light emitting element ED1 emits light in the first mode can be output only at a high level which is a turn-off level. In addition, as illustrated in FIG. 5B, the first selection signal Ss for controlling the emission of the first light emitting element ED1 so that only the second light emitting element ED2 emits light in the second mode can be output only at the high level (or first level) which is the turn-off level.

Specifically, looking at the first mode, which is the share mode, with reference to FIGS. 4 and 5A, during an initialization period P1, the low-level second scan signal SCAN2, the low-level first selection signal Ss, and the low-level emission signal EM can be output. The second switching transistor ST2, the fourth switching transistor ST4, and the fifth switching transistor ST5 can be turned on by the low-level second scan signal SCAN2, the first selection transistor TP1 can be turned on by the low-level first selection signal Ss, and the third switching transistor ST3 and the sixth switching transistor ST6 can be turned on by the low-level emission signal EM.

The first node N1 can be initialized to the reference voltage Vref through the turned-on third switching transistor ST3. The voltage of the anode electrode of the first light emitting element ED1 through the turned-on fourth switching transistor ST4 can be initialized to the reference voltage Vref, and the voltage of the anode electrode of the second light emitting element ED2 through the turned-on fifth switching transistor ST5 can be initialized to the reference voltage Vref. The driving transistor DT is diode-connected through the turned-on second switching transistor ST2, and the gate electrode and drain electrode of the driving transistor DT is short-circuited, so the driving transistor DT can operate like a diode. The reference voltage Vref transmitted to the anode electrode of the first light emitting element ED1 through the turned-on fourth switching transistor ST4 is transmitted to the third node N3 and the second node N2 through the turned-on first selection transistor TP1 and the turned-on sixth switching transistor ST6, so the third node N3 and the second node N2 can also be initialized to the reference voltage Vref.

Next, during a sampling period P2, the low-level first scan signal SCAN1 and the low-level second scan signal SCAN2 can be output, and the first selection signal Ss can be output at the high level. The high-level emission signal EM is output, and thus, the third switching transistor ST3 is turned off, and at the same time, the first switching transistor ST1 is turned on by the low-level (or second level, in which the second level has a lower value than the first level) first scan signal SCAN1, so the data voltage Vdata can be transmitted to the first node N1. The driving transistor DT can be diode-connected by the turned-on second switching transistor ST2, and a difference voltage between the high-potential power voltage VDD and the threshold voltage can be sampled and supplied to the second node N2.

Meanwhile, during the sampling period P2, the sixth switching transistor ST6 can be turned off by the high-level emission signal EM, and the first selection transistor TP1 can be turned off by the high-level first selection signal Ss.

During a holding period P3, the first scan signal SCAN1 and the second scan signal SCAN2 can be output at the high level, and the first switching transistor ST1, the second switching transistor ST2, the fourth switching transistor ST4, and the fifth switching transistor ST5 can all be turned off. However, even if the first switching transistor ST1 is turned off, the data voltage Vdata input in the previous sampling period (e.g., sampling period P2) can be maintained by the storage capacitor Cst.

Finally, during an emission period P4, the low-level first selection signal Ss and the low-level emission signal EM can be output, and the high-level second selection signal Ps can be output. The reference voltage Vref is applied to the first node N1 through the third switching transistor ST3 turned on by the low-level emission signal EM and the voltage of the first node N1 can be the difference voltage between the reference voltage Vref and the data voltage Vdata. This voltage change can also be reflected in the second node N2. The gate-source voltage of the driving transistor DT can be set to a value of Vdata−Vref+Vth obtained by subtracting the reference voltage Vref and adding a threshold voltage Vth of the driving transistor DT from the data voltage Vdata to control the first driving current.

The first driving current is supplied from the driving transistor DT to the first light emitting element ED1 through the sixth switching transistor ST6 turned on by the low-level emission signal EM and the first selection transistor TP1 turned on by the low-level first selection signal Ss, so the first light emitting element ED1 can emit light. However, the second selection signal Ps is output at the high level, and thus, the second selection transistor TP2 is turned off, so the second driving current is not transmitted from the driving transistor DT to the second light emitting element ED2. Accordingly, when the first pixel circuit PC1 is driven in the first mode, the first driving current is applied only to the first light emitting element ED1, so only the first light emitting element ED1 can emit light.

Next, looking at the second mode, which is the private mode, with reference to FIGS. 4 and 5B, the first pixel circuit PC1 can be driven in the second mode in substantially the same manner as in the first mode, except that the first selection signal Ss and the second selection signal Ps are output opposite to those in the first mode which is the share mode. For example, the first selection signal Ss can be output only at the high level which is the turn-off level, and the second selection signal Ps can be output at the low level which is the turn-on level, during the emission period P4 when the second light emitting element ED2 emits light.

Specifically, during the initialization period P1, the first scan signal SCAN1 can be output at the high level, and the second scan signal SCAN2 can be output at the low level. In addition, the first selection signal Ss can be output at the high level, and the second selection signal Ps and the emission signal EM can be output at the low level. Accordingly, the second switching transistor ST2, the fourth switching transistor ST4, and the fifth switching transistor ST5 can be turned on by the second scan signal SCAN2, the second selection transistor TP2 can be turned on by the second selection signal Ps, and the third switching transistor ST3 and the sixth switching transistor ST6 can be turned on by the emission signal EM.

The first node N1 can be initialized to the reference voltage Vref through the third switching transistor ST3 turned on by the emission signal EM, and the anode electrodes of the first light emitting element ED1 and the second light emitting element ED2 can be initialized to the reference voltage Vref by each of the fourth switching transistor ST4 and the fifth switching transistor ST5 turned on by the second scan signal SCAN2. The driving transistor DT can be diode-connected through the turned-on second switching transistor ST2 and operate like a diode. Finally, the reference voltage Vref transmitted to the anode electrode of the second light emitting element ED2 through the turned-on fifth switching transistor ST5 can be transmitted to the third node N3 and the second node N2 through the turned-on second selection transistor TP2 and the turned-on sixth switching transistor ST6, so the third node N3 and the second node N2 can be initialized to the reference voltage Vref.

Next, during the sampling period P2, the low level first scan signal SCAN1 and the low-level second scan signal SCAN2 can be output, and the second selection signal Ps and the emission signal EM can be output from the low level to the high level. The high-level emission signal EM is output, so the third switching transistor ST3 can be turned off, and the first switching transistor ST1 is turned on by the low-level first scan signal SCAN1, so the data voltage Vdata can be transmitted to the first node N1. The driving transistor DT can be diode-connected by the turned-on second switching transistor ST2, and a difference voltage between the high-potential power voltage VDD and the threshold voltage can be sampled and supplied to the second node N2.

Meanwhile, during the sampling period P2, the sixth switching transistor ST6 can be turned off by the high-level emission signal EM, and the second selection transistor TP2 can be turned off by the high-level second selection signal Ps.

Finally, during the emission period P4, the low-level second selection signal Ps and the low-level emission signal EM can be output, and the high-level first selection signal Ss can be output. The reference voltage Vref is applied to the first node N1 through the third switching transistor ST3 turned on by the low-level emission signal EM, and the voltage of the first node N1 can be the difference voltage between the reference voltage Vref and the data voltage Vdata. This voltage change can also be reflected in the second node N2. The gate-source voltage of the driving transistor DT can be set to a value of Vdata−Vref+Vth obtained by subtracting the reference voltage Vref and adding a threshold voltage Vth of the driving transistor DT from the data voltage Vdata to control the second driving current.

The second driving current is supplied from the driving transistor DT to the second light emitting element ED2 through the sixth switching transistor ST6 turned on by the low-level emission signal EM and the second selection transistor TP2 turned on by the low-level second selection signal Ps, so the second light emitting element ED2 can emit light. However, the first selection signal Ss is output at the high level, and thus, the first selection transistor TP1 is turned off, so the first driving current is not transmitted from the driving transistor DT to the first light emitting element ED1. Accordingly, when the first pixel circuit PC1 is driven in the second mode, the second driving current is applied only to the second light emitting element ED2, so only the second light emitting element ED2 can emit light.

FIGS. 6 and 7 are cross-sectional views of a portion of the display device according to the example embodiment of the present disclosure.

Particularly, FIG. 6 illustrates a pixel in which a first optical member 161 is disposed, and FIG. 7 illustrates a pixel in which a second optical member 162 is disposed.

Referring to FIGS. 6 and 7, the display device 100 according to an example embodiment of the present disclosure includes a substrate 110, a buffer film 111, a gate insulating film 112, an interlayer insulating film 113, a lower protection film 114, an overcoat layer 115, a bank insulating film 116, the first selection transistor TP1, the second selection transistor TP2, the first light emitting element ED1, the second light emitting element ED2, the first optical member 161, the second optical member 162, an optical member protection film 170, and an encapsulation member 180.

The substrate 110 can include an insulating material. The substrate 110 can include a transparent material. For example, the substrate 110 can include glass or plastic.

The buffer film 111 can be disposed on the substrate 110. The buffer film 111 can include an insulating material. For example, the buffer film 111 can include an inorganic insulating material such as silicon oxide (SiOx) and silicon nitride (SiNx). The buffer film 111 can have a multi-layer structure. For example, the buffer film 111 can have a stacked structure of a film formed of silicon nitride (SiNx) and a film formed of silicon oxide (SiOx).

The buffer film 111 can be located between the substrate 110 and a driving part of each pixel PX. The buffer film 111 can prevent contamination by the substrate 110 during the process of forming the driving part. For example, a top surface of the substrate 110 facing a driving part of each pixel PX can be covered with the buffer film 111. The driving part of each pixel PX can be located on the buffer film 111.

The gate insulating film 112 can be disposed on the buffer film 111. The gate insulating film 112 can include an insulating material. For example, the gate insulating film 112 can include an inorganic insulating material such as silicon oxide (SiOx) and silicon nitride (SiNx). The gate insulating film 112 can include a material with a high dielectric constant. For example, the gate insulating film 112 can include a high-K material such as hafnium oxide (HfO). The gate insulating film 112 can have a multi-layer structure.

The gate insulating film 112 can extend between the semiconductor layers 121 and 221 and the gate electrodes 122 and 223 of the selection transistors TP1 and TP2. For example, the gate electrodes of the driving transistor and the switching transistor can be insulated from the semiconductor layers of the driving transistor and the switching transistor by the gate insulating film 112. The gate insulating film 112 can cover the semiconductor layer of each pixel PX. The gate electrodes of the driving transistor and the switching transistor can be located on the gate insulating film 112.

The interlayer insulating film 113 can be disposed on the gate insulating film 112. The interlayer insulating film 113 can include the gate insulating film 112. For example, the interlayer insulating film 113 can include an inorganic insulating material such as silicon oxide (SiOx) and silicon nitride (SiNx). The interlayer insulating film 113 can extend between the gate electrodes and the source electrodes and between the gate electrodes and the drain electrodes of each of the driving transistor DT and the switching transistor. For example, the source electrodes and drain electrodes of each of the driving transistor and the switching transistor can be insulated from the gate electrode by the interlayer insulating film 113. The interlayer insulating film 113 can cover the gate electrodes of each of the driving transistor and the switching transistor. The source electrodes and drain electrodes of each pixel PX can be located on the interlayer insulating film 113. The gate insulating film 112 and the interlayer insulating film 113 can expose source regions and drain regions of each semiconductor pattern located within each pixel PX.

The lower protection film 114 can be disposed on the interlayer insulating film 113. The lower protection film 114 can include an insulating material. For example, the lower protection film 114 can include an inorganic insulating material such as silicon oxide (SiOx) and silicon nitride (SiNx). The lower protection film 114 can prevent the driving part from being damaged due to external moisture and impact. The lower protection film 114 can extend along the surfaces of the driving transistor and the switching transistor facing the substrate 110. The lower protection film 114 can contact the interlayer insulating film 113 outside the driving part located within each pixel PX.

The overcoat layer 115 can be disposed on the lower protection film 114. The overcoat layer 115 can include an insulating material. The overcoat layer 115 can include a material different from that of the lower protection film 114. For example, the overcoat layer 115 can include an organic insulating material. The overcoat layer 115 can remove steps caused by the driving part of each pixel PX. For example, the top surface of the overcoat layer 115 facing a device substrate 110 can be a flat surface.

The first selection transistor TP1 and the second selection transistor TP2 can be disposed on the substrate 110. The first selection transistor TP1 can be electrically connected between the drain electrode of the driving transistor DT and the first lower electrode 141 of the first light emitting element ED1. The second selection transistor TP2 can be electrically connected between the drain electrode of the driving transistor DT and the second lower electrode 151 of the second light emitting element ED2.

The first selection transistor TP1 can include a first semiconductor layer 121, a first gate electrode 122, a first source electrode 123, and a first drain electrode 124. The first selection transistor TP1 can have the same structure as the switching transistor and driving transistor. For example, the first semiconductor layer 121 can be located between the buffer film 111 and the gate insulating film 112, and the first gate electrode 122 can be located between the gate insulating film 112 and the interlayer insulating film 113. The first source electrode 123 and the first drain electrode 124 can be located between the interlayer insulating film 113 and the lower protection film 114. The first gate electrode 122 can overlap a channel region of the first semiconductor layer 121. The first source electrode 123 can be electrically connected to the source region of the first semiconductor layer 121. The first drain electrode 124 can be electrically connected to the drain region of the first semiconductor layer 121.

The second selection transistor TP2 can include a second semiconductor layer 221, a second gate electrode 223, a second source electrode 225, and a second drain electrode 227. For example, the second semiconductor layer 221 can be located on the same layer as the first semiconductor layer 121, the second gate electrode 223 can be located on the same layer as the first gate electrode 122, and the second source electrode 225 and the second drain electrode 227 can be located on the same layer as the first source electrode 123 and the first drain electrode 124.

The first light emitting element ED1 and the second light emitting element ED2 of each pixel PX can be disposed on the overcoat layer 115 of the corresponding pixel PX.

The first light emitting element ED1 can emit light representing a specific color. For example, the first light emitting element ED1 can include a first lower electrode 141, a first light emitting layer 142, and a first upper electrode 143 sequentially stacked on the substrate 110.

The first lower electrode 141 can include a conductive material. The first lower electrode 141 can include a material with high reflectivity. For example, the first lower electrode 141 can include metal such as aluminum (Al) and silver (Ag). The first lower electrode 141 can have a multi-layer structure. For example, the first lower electrode 141 can have a structure in which a reflective electrode formed of metal is located between transparent electrodes formed of transparent conductive materials such as ITO and IZO. The first lower electrode 141 can be electrically connected to the first drain electrode 124 of the first selection transistor TP1 through a contact hole penetrating through the lower protection film 114 and the overcoat layer 115.

The first light emitting layer 142 can generate light with a luminance corresponding to a voltage difference between the first lower electrode 141 and the first upper electrode 143. For example, the first light emitting layer 142 can include an emission material layer (EML) including an emission material. The emission material can include organic materials, inorganic materials, or hybrid materials.

The first light emitting layer 142 can have a multi-layer structure. For example, the first light emitting layer 142 can further include at least one of a hole injection layer (HIL), a hole transport layer (HTL), an electron transport layer (ETL), and an electron injection layer (EIL).

The first upper electrode 143 can include a conductive material. The first upper electrode 143 can include a material different from that of the first lower electrode 141. A transmittance of the first upper electrode 143 can be higher than that of the first lower electrode 141. For example, the first upper electrode 143 can be a transparent electrode formed of a transparent conductive material such as ITO and IZO. Accordingly, in the display device 100 according to an example embodiment of the present disclosure, the light generated by the first light emitting layer 142 can be emitted through the first upper electrode 143.

The second light emitting element ED2 can implement the same color as the first light emitting element ED1. The second light emitting element ED2 can have the same structure as the first light emitting element ED1. For example, the second light emitting element ED2 can include a second lower electrode 151, a second light emitting layer 152, and a second upper electrode 153 sequentially stacked on the substrate 110.

The second lower electrode 151 can correspond to the first lower electrode 141, the second light emitting layer 152 can correspond to the first light emitting layer 142, and the second upper electrode 153 can correspond to the first upper electrode 143. For example, the second lower electrode 151 can be formed for the second light emitting element ED2 in the same structure as the first lower electrode 141, which is the same for the second light emitting layer 152 and the second upper electrode 153. For example, the first light emitting element ED1 and the second light emitting element ED2 can be formed to have the same structure. However, the present disclosure is not limited thereto, and in some cases, at least some components of the first light emitting element ED1 and the second light emitting element ED2 can be formed differently.

The second light emitting layer 152 can be spaced apart from the first light emitting layer 142. Accordingly, in the display device according to an example embodiment of the present disclosure, the emission due to leakage current can be prevented.

According to an example embodiment of the present disclosure, in the display device, light can be generated only from one of the first light emitting layer 142 and the second light emitting layer 152 according to the user selection or the pre-specified conditions.

The second lower electrode 151 of each pixel PX can be spaced apart from the first lower electrode 141 of the corresponding pixel PX. For example, a bank insulating film 116 can be disposed between the first lower electrode 141 and the second lower electrode 151 of each pixel PX. The bank insulating film 116 can include an insulating material. For example, the bank insulating film 116 can include an organic insulating material. The bank insulating film 116 can include a material different from that of the overcoat layer 115.

The second lower electrode 151 of each pixel PX can be insulated from the first lower electrode 141 of the corresponding pixel PX by the bank insulating film 116. For example, the bank insulating film 116 can cover an edge of the first lower electrode 141 and an edge of the second lower electrode 151 located within each pixel PX. Accordingly, in the display device 100, an image from the first optical area of each pixel PX where the first light emitting element ED1 is located or an image from the second optical area of each pixel PX where the second light emitting element ED2 is located can be provided to a user.

The first light emitting layer 142 and the first upper electrode 143 of the first light emitting element ED1 located within each pixel PX can be stacked on a partial area of the corresponding first lower electrode 141 exposed by the bank insulating film 116. The second light emitting layer 152 and the second upper electrode 153 of the second light emitting element ED2 located within each pixel PX can be stacked on a partial area of the corresponding second lower electrode 151 exposed by the bank insulating film 116. For example, the bank insulating film 116 can distinguish within each pixel PX between a first emission area where light is emitted from the first light emitting element ED1 and a second emission area where light is emitted from the second light emitting element ED2. The size of the second emission area divided within each pixel PX can be smaller than that of the first emission area.

The second upper electrode 153 of each pixel PX can be electrically connected to the first upper electrode 143 of the corresponding pixel PX. For example, the voltage applied to the second upper electrode 153 of the second light emitting element ED2 located within each pixel PX can be the same as the voltage applied to the first upper electrode 143 of the first light emitting element ED1 located within the corresponding pixel PX. The second upper electrode 153 of each pixel PX can include the same material as the first upper electrode 143 of the corresponding pixel PX. For example, the second upper electrode 153 of each pixel PX can be formed simultaneously with the first upper electrode 143 of the corresponding pixel PX. The second upper electrode 153 of each pixel PX can extend onto the bank insulating film 116 and directly contact the first upper electrode 143 of the corresponding pixel PX. The luminance of the first optical area and the luminance of the second optical area located within each pixel PX can be controlled by the driving current generated in the corresponding pixel PX.

The encapsulation member 180 can be located on the first light emitting element ED1 and the second light emitting element ED2 of each pixel PX. The encapsulation member 180 can prevent the light emitting elements ED1 and ED2 from being damaged due to external moisture and impact. The encapsulation member 180 can have a multi-layer structure. For example, the encapsulation member 180 can include a first encapsulation layer 181, a second encapsulation layer 182, and a third encapsulation layer 183 that are sequentially stacked, but is not limited thereto. The first encapsulation layer 181, the second encapsulation layer 182, and the third encapsulation layer 183 can include an insulating material. The second encapsulation layer 182 can include a material different from the first encapsulation layer 181 and the third encapsulation layer 183. For example, the first encapsulation layer 181 and the third encapsulation layer 183 are inorganic encapsulation layers including an inorganic insulating material, and the second encapsulation layer 182 can include an organic encapsulation layer including an organic insulating material. Accordingly, the light emitting elements ED1 and ED2 of the display device 100 can be more effectively prevented from being damaged due to external moisture and impact.

The first optical member 161 and the second optical member 162 can be disposed on the encapsulation member 180.

The first optical member 161 can be disposed on the first light emitting element ED1. The light generated by the first light emitting element ED1 of each pixel PX can be emitted through the first optical member 161 disposed in the first optical area of the corresponding pixel PX. The first optical member 161 can have a shape in which light in at least one direction is not limited. For example, the planar shape of the first optical member 161 located within each pixel PX can have a bar shape extending in one direction.

In this case, the travel direction of the light emitted from the first optical area of each pixel PX may not be limited to one direction. For example, the content (or images) provided through the first optical area of each pixel PX can be shared with people around a user who are adjacent to the user in one direction. Accordingly, the content provided by the light emitted through the first optical member 161 will be provided in a first viewing angle range which is a wide viewing angle than the content provided by the light emitted through the second optical member 162. For example, the content provided by light emitted through the first optical member 161 can be provided in the share mode.

The second optical member 162 can be disposed on the second light emitting element ED2. The light generated by the second light emitting element ED2 of each pixel PX can be emitted through the second optical member 162 disposed in the second optical area of the corresponding pixel PX. The second optical member 162 can limit the travel direction of passing light to one direction and/or the other direction. For example, the planar shape of the optical member 162 located within each pixel PX can have a circular shape.

In this case, the travel direction of light emitted from the second optical area of each pixel PX can be limited to one direction and/or the other direction. For example, the content (or images) provided by the second optical area of each pixel PX may not be shared with people around a user. Accordingly, the content provided by the light emitted through the second optical member 162 can be provided in a second viewing angle range which is a narrower viewing angle than the content provided by the light emitted through the first optical member 161. For example, the content provided by the light emitted through the second optical member 162 can be provided in the private mode.

The first emission areas of each pixel PX can have a shape corresponding to the first optical member 161 of the corresponding pixel PX. For example, the planar shape of the first emission areas of each pixel PX can have a bar shape extending in one direction. The first optical member 161 can have a size larger than the first emission area of the corresponding pixel PX. Accordingly, the efficiency of light emitted from the first emission area of the pixel PX can be improved.

The second emission area of each pixel PX can have a shape corresponding to the second optical member 162 of the corresponding pixel PX. For example, the planar shape of the second light emitting area of each pixel PX can have a circular shape. The second optical member 162 can have a size larger than the second emission area of the corresponding pixel PX. Accordingly, the efficiency of light emitted from the second emission area of the pixel PX can be improved.

The optical member protection film 170 can be located on the first optical member 161 and the second optical member 162 of the pixel PX. The optical member protection film 170 can include an insulating material. For example, the optical member protection film 170 can include an organic insulating material. The refractive index of the optical member protection film 170 can be smaller than the refractive indexes of the first optical member 161 and the second optical member 162 located within each pixel PX. Accordingly, in the display device 100 according to an example embodiment of the present disclosure, light passing through the first optical member 161 and the second optical member 162 of each pixel PX may not be reflected toward the substrate 110 due to a difference in refractive index from the optical member protection film 170.

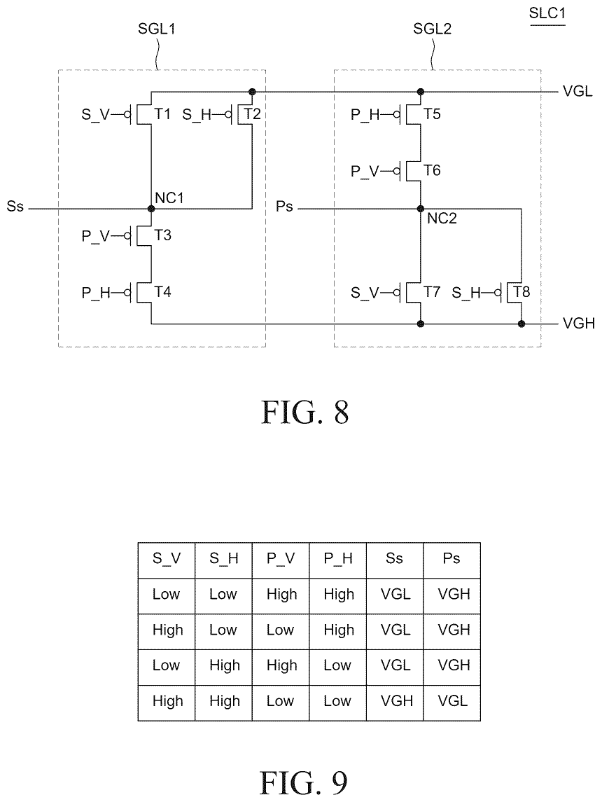

FIG. 8 is a circuit diagram illustrating an example of a selection signal generation circuit included in the display device of FIG. 2.

Meanwhile, the first selection signal generation circuit SLC1 illustrated in FIG. 8 represents an example embodiment of the selection signal generation circuits corresponding to each of the plurality of selection signal generators SLG included in the display device 100 described with reference to FIGS. 2 to 3E. The selection signal generator SLG including the first selection signal generation circuit SLC1 can provide a selection signal to the pixel PX including the first pixel circuit PC1 described with reference to FIG. 4.

Referring to FIG. 8, the plurality of transistors included in the first selection signal generation circuit SLC1 can be n-type transistors or p-type transistors. In the case of the p-type transistor, a low-level voltage of each control signal refers to a voltage that turns on TFT, and a high-level voltage of each control signal can refer to a voltage that turns off TFTs. Hereinafter, for convenience of description, the description will be made on the basis that the plurality of transistors T1 to T8 included in the first selection signal generation circuit SLC1 are p-type transistors. However, at least some of the plurality of transistors T1 to T8 included in the first selection signal generation circuit SLC1 can be modified and implemented as n-type transistors.

The first electrode or second electrode of the transistor, which will be described below, can refer to the source electrode or the drain electrode. However, the terms “first electrode and second electrode” are only terms for distinguishing each electrode and do not limit what corresponds to each electrode. In addition, the first electrode for each electrode may not refer to the same electrode.

The first selection signal generation circuit SLC1 can include a first selection signal output unit SGL1 that generates the first selection signal Ss based on first to fourth control signals S_V, S_H, P_V, and P_H, a first power voltage VGH, and a second power voltage VGL and a second selection signal output unit SLG2 that generates the second selection signal Ps based on the first to fourth control signals S_V, S_H, P_V, and P_H, the first power voltage VGH, and the second power voltage VGL.

The first power voltage VGH and the second power voltage VGL are driving voltages for driving the first selection signal generation circuit SLC1, and the voltage level of the second power voltage VGL can be lower than that of the first power voltage VGH. For example, the first power voltage VGH can be a positive voltage, and the second power voltage VGL can be a negative voltage.

The first selection signal output unit SGL1 can control a voltage of a first output node NC1 to the high-level first power voltage VGH or the low-level second power voltage VGL, thereby configured to output the high-level or low-level first selection signal Ss, for example, the turn-off level or turn-on level first selection signal Ss through the first output node NC1. To this end, the first selection signal output unit SGL1 can include first to fourth transistors T1 to T4.

The first transistor T1 can be connected between the second power voltage line configured to provide the second power voltage VGL and the first output node NC1. For example, the first electrode of the first transistor T1 can be connected to the second power voltage line, and the second electrode of the first transistor T1 can be connected to the first output node NC1. The gate electrode of the first transistor T1 can be connected to a first control signal line that provides the first control signal S_V. The first transistor T1 can be turned on when the turn-on level (e.g., low-level) first control signal S_V is supplied to electrically connect the first output node NC1 and the second power voltage line. In this case, the second power voltage VGL is provided to the first output node NC1, so the first selection signal output unit SGL1 can output the low-level first selection signal Ss.

The second transistor T2 can be connected between the second power voltage line configured to provide the second power voltage VGL and the first output node NC1. For example, the first electrode of the second transistor T2 can be connected to the second power voltage line, and the second electrode of the second transistor T2 can be connected to the first output node NC1. The gate electrode of the second transistor T2 can be connected to a second control signal line that provides the second control signal S_H. The second transistor T2 can be turned on when the turn-on level (e.g., low-level) second control signal S_H is supplied to electrically connect the first output node NC1 and the second power voltage line. In this case, the second power voltage VGL is provided to the first output node NC1, so the first selection signal output unit SGL1 can output the low-level first selection signal Ss.

The third transistor T3 can be connected between the first power voltage line configured to provide the first power voltage VGH and the first output node NC1. For example, the first electrode of the third transistor T3 can be connected to the fourth transistor T4, and the second electrode of the third transistor T3 can be connected to the first output node NC1. The gate electrode of the third transistor T3 can be connected to a third control signal line that provides the third control signal P_V. The third transistor T3 can be turned on when the turn-on level (e.g., low-level) third control signal P_V is supplied to electrically connect the first output node NC1 and the fourth transistor T4.

The fourth transistor T4 can be connected between the third transistor T3 and the first power voltage line that provides the first power voltage VGH. For example, the first electrode of the fourth transistor T4 can be connected to the first power voltage line, and the second electrode of the fourth transistor T4 can be connected to the first electrode of the third transistor T3. The gate electrode of the fourth transistor T4 can be connected to a fourth control signal line that provides the fourth control signal P_H. The fourth transistor T4 can be turned on when the turn-on level (e.g., low-level) fourth control signal P_H is supplied to electrically connect the third transistor T3 and the first power voltage line.

The first transistor T1 and the second transistor T2 can be connected in parallel between the second power voltage line configured to provide the second power voltage VGL and the first output node NC1. Accordingly, when at least one of the first transistor T1 and the second transistor T2 is turned on, the first output node NC1 and the second power voltage line configured to provide the second power voltage VGL can be electrically connected, so the low-level first selection signal Ss can be output through the first output node NC1.

In addition, the third transistor T3 and the fourth transistor T4 can be connected in series between the first power voltage line configured to provide the first power voltage VGH and the first output node NC1. Accordingly, when both the third transistor T3 and the fourth transistor T4 are turned on, the first output node NC1 and the first power voltage line configured to provide the first power voltage VGH can be electrically connected, so the high-level first selection signal Ss can be output through the first output node NC1.

In this way, the first transistor T1 and the second transistor T2 can function as a pull-up unit of the first selection signal output unit SGL1, and the third transistor T3 and the fourth transistor T4 can function as a pull-down unit of the first selection signal output unit SGL1. For example, the first transistor T1 and the second transistor T2 can be defined as a first pull-up unit, and the third transistor T3 and the fourth transistor T4 can be defined as a first pull-down unit.

The second selection signal output unit SGL2 can control a voltage of a second output node NC2 to the high-level first power voltage VGH or the low-level second power voltage VGL, thereby configured to output the high-level or low-level second selection signal Ps, for example, the turn-off level or turn-on level second selection signal Ps through the second output node NC2. To this end, the second selection signal output unit SGL2 can include the fifth to eighth transistors T5 to T8.

The fifth transistor T5 can be connected between the second power voltage line configured to provide the second power voltage VGL and the second output node NC2. For example, the first electrode of the fifth transistor T5 can be connected to the second power voltage line, and the second electrode of the fifth transistor T5 can be connected to the sixth transistor T6. The gate electrode of the fifth transistor T5 can be connected to a fourth control signal line that provides the fourth control signal P_H. The fifth transistor T5 can be turned on when the turn-on level (e.g., low-level) fourth control signal P_H is supplied to electrically connect the second power voltage line and the sixth transistor T6.

The sixth transistor T6 can be connected between the fifth transistor T5 and the second output node NC2. For example, the first electrode of the sixth transistor T6 can be connected to the second electrode of the fifth transistor T5, and the second electrode of the sixth transistor T6 can be connected to the second output node NC2. The gate electrode of the sixth transistor T6 can be connected to a third control signal line that provides the third control signal P_V. The sixth transistor T6 can be turned on when the turn-on level (e.g., low-level) third control signal P_V is supplied to electrically connect the fifth transistor T5 and the second output node NC2.

The seventh transistor T7 can be connected between the first power voltage line configured to provide the first power voltage VGH and the second output node NC2. For example, the first electrode of the seventh transistor T7 can be connected to the first power voltage line, and the second electrode of the seventh transistor T7 can be connected to the second output node NC2. The gate electrode of the seventh transistor T7 can be connected to a first control signal line that provides the first control signal S_V. The seventh transistor T7 can be turned on when the turn-on level (e.g., low-level) first control signal S_V is supplied to electrically connect the second output node NC2 and the first power voltage line. In this case, the first power voltage VGH is provided to the second output node NC2, so the second selection signal output unit SGL2 can output the high-level second selection signal Ps.

The eighth transistor T8 can be connected between the first power voltage line configured to provide the first power voltage VGH and the second output node NC2. For example, the first electrode of the eighth transistor T8 can be connected to the first power voltage line, and the second electrode of the eighth transistor T8 can be connected to the second output node NC2. The gate electrode of the eighth transistor T8 can be connected to a second control signal line that provides the second control signal S_H. The eighth transistor T8 can be turned on when the turn-on level (e.g., low-level) second control signal S_H is supplied to electrically connect the second output node NC2 and the first power voltage line. In this case, the first power voltage VGH is provided to the second output node NC2, so the second selection signal output unit SGL2 can output the high-level second selection signal Ps.

The fifth transistor T5 and the sixth transistor T6 can be connected in series between the second power voltage line configured to provide the second power voltage VGL and the second output node NC2. Accordingly, when both the fifth transistor T5 and the sixth transistor T6 are turned on, the second output node NC2 and the second power voltage line configured to provide the second power voltage VGL can be electrically connected, so the low-level second selection signal Ps can be output through the second output node NC2.

In addition, the seventh transistor T7 and the eighth transistor T8 can be connected in parallel between the first power voltage line configured to provide the first power voltage VGH and the second output node NC2. Accordingly, when at least one of the seventh transistor T7 and the eighth transistor T8 is turned on, the second output node NC2 and the first power voltage line configured to provide the first power voltage VGH can be electrically connected, so the high-level second selection signal Ps can be output through the second output node NC2.

In this way, the fifth transistor T5 and the sixth transistor T6 can function as a pull-up unit of the second selection signal output unit SGL2, and the seventh transistor T7 and the eighth transistor T8 can function as a pull-down unit of the second selection signal output unit SGL2. For example, the fifth transistor T5 and the sixth transistor T6 can be defined as a second pull-up unit, and the seventh transistor T7 and the eighth transistor T8 can be defined as a second pull-down unit.

FIG. 9 is a diagram for describing an example of an operation of the selection signal generation circuit of FIG. 8.

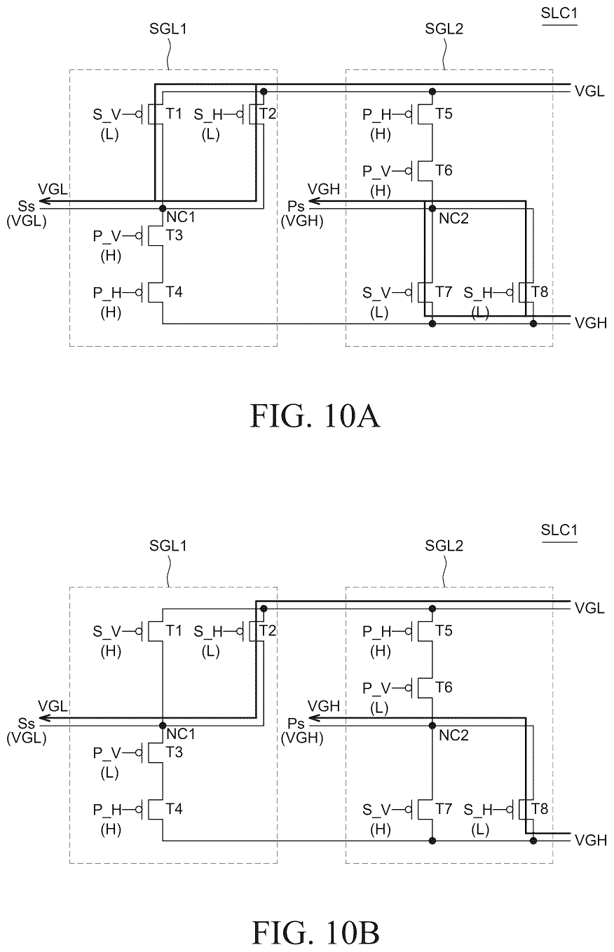

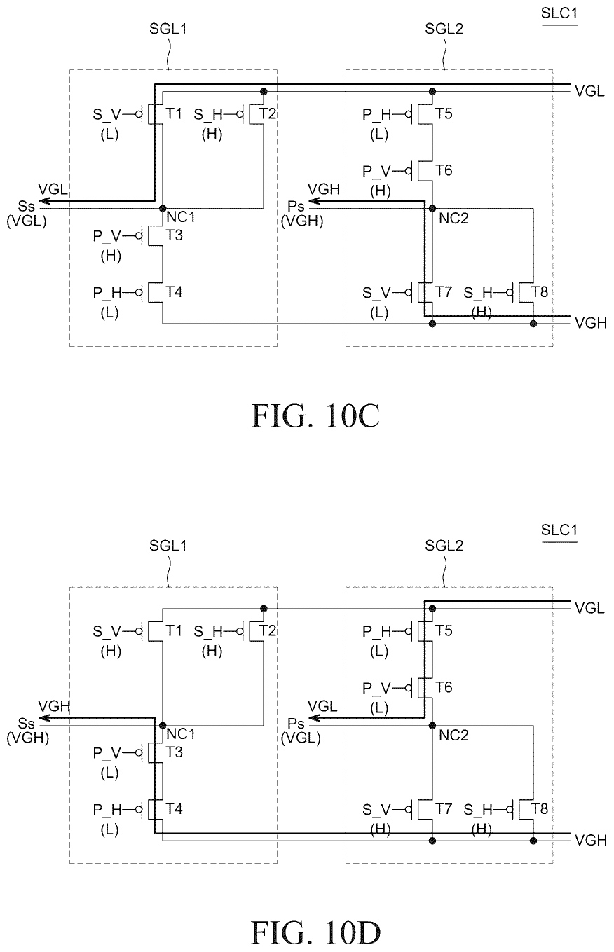

FIGS. 10A to 10D are equivalent circuit diagrams for describing an example of the operation of the selection signal generation circuit of FIG. 8.

Referring to FIGS. 8 and 9, the first selection signal generation circuit SLC1 can output the low-level first selection signal Ss and the high-level second selection signal Ps or can output the high-level first selection signal Ss and the low-level second selection signal Ps based on the first to fourth control signals S_V, S_H, P_V, and P_H. For example, the first selection signal generation circuit SLC1 can output the first selection signal Ss and the second selection signal Ps having opposite voltage levels.

For example, further referring to FIG. 10A, when the first control signal S_V and the second control signal S_H are a low level (i.e., turn-on level), and the third control signal P_V and the fourth control signal P_H are the high level (i.e., turn-off level), the first transistor T1, the second transistor T2, the seventh transistor T7, and the eighth transistor T8 can be turned on, and the third transistor T3, the fourth transistor T4, the fifth transistor T5, and the sixth transistor T6 can be turned off.

In this case, the second power voltage VGL provided from the second power voltage line is provided to the first output node NC1 through the turned-on first transistor T1 or the turned-on second transistor T2, so the first selection signal Ss having the low level (i.e., turn-on level) of the second power voltage VGL can be output. In addition, the first power voltage VGH provided from the first power voltage line is provided to the second output node NC2 through the turned-on seventh transistor T7 or the turned-on eighth transistor T8, so the second selection signal Ps having the high level (i.e., turn-on level) of the first power voltage VGH can be output.

Next, further referring to FIG. 10B, when the second control signal S_H and the third control signal P_V are a low level (i.e., turn-on level), and the first control signal S_V and the fourth control signal P_H are the high level (i.e., turn-off level), the second transistor T2, the third transistor T3, the sixth transistor T6, and the eighth transistor T8 can be turned on, and the first transistor T1, the fourth transistor T4, the fifth transistor T5, and the seventh transistor T7 can be turned off.

In this case, the second power voltage VGL provided from the second power voltage line is provided to the first output node NC1 through the turned-on second transistor T2, so the first selection signal Ss having the low level (i.e., turn-on level) of the second power voltage VGL can be output. In addition, the first power voltage VGH provided from the first power voltage line is provided to the second output node NC2 through the turned-on eighth transistor T8, so the second selection signal Ps having the high level (i.e., turn-on level) of the first power voltage VGH can be output.

Meanwhile, even if the third transistor T3 is turned on, the fourth transistor T4 connected in series with the third transistor T3 is turned off, so the first power voltage VGH is not provided to the first output node NC1. Similarly, even if the sixth transistor T6 is turned on, the fifth transistor T5 connected in series with the sixth transistor T6 is turned off, so the second power voltage VGL is not provided to the second output node NC2.

Next, further referring to FIG. 10C, when the second control signal S_H and the third control signal P_V are the high level (i.e., turn-off level), and the first control signal S_V and the fourth control signal P_H are a low level (i.e., turn-on level), the second transistor T2, the third transistor T3, the sixth transistor T6, and the eighth transistor T8 can be turned off, and the first transistor T1, the fourth transistor T4, the fifth transistor T5, and the seventh transistor T7 can be turned on.

In this case, the second power voltage VGL provided from the second power voltage line is provided to the first output node NC1 through the turned-on first transistor T1, so the first selection signal Ss having the low level (i.e., turn-on level) of the second power voltage VGL can be output. In addition, the first power voltage VGH provided from the first power voltage line is provided to the second output node NC2 through the turned-on seventh transistor T7, so the second selection signal Ps having the high level (i.e., turn-off level) of the first power voltage VGH can be output.

Meanwhile, even if the fourth transistor T4 is turned on, the third transistor T3 connected in series with the fourth transistor T4 is turned off, so the first power voltage VGH is not provided to the first output node NC1. Similarly, even if the fifth transistor T5 is turned on, the sixth transistor T6 connected in series with the fifth transistor T5 is turned off, so the second power voltage VGL is not provided to the second output node NC2.

Finally, further referring to FIG. 10D, when the first control signal S_V and the second control signal S_H are the high level (i.e., turn-off level), and the third control signal P_V and the fourth control signal P_H are a low level (i.e., turn-on level), the first transistor T1, the second transistor T2, the seventh transistor T7, and the eighth transistor T8 can be turned off, and the third transistor T3, the fourth transistor T4, the fifth transistor T5, and the sixth transistor T6 can be turned on.

In this case, the first power voltage VGH provided from the first power voltage line is provided to the first output node NC1 through the turned-on third transistor T3 and the turned-on fourth transistor T4 connected in series to each other, so the first selection signal Ss having the high level (i.e., turn-off level) of the first power voltage VGH can be output. In addition, the second power voltage VGL provided from the second power voltage line is provided to the second output node NC2 through the turned-on fifth transistor T5 and the turned-on sixth transistor T6 connected in series to each other, so the second selection signal Ps having the low level (i.e., turn-on level) of the second power voltage VGL can be output.

In this way, the first selection signal generation circuit SLC1 can control the driving mode of the pixel PX by configured to provide the first selection signal Ss and the second selection signal Ps, which have opposite voltage levels, to the pixel PX.

For example, when the low-level first selection signal Ss and the high-level second selection signal Ps are provided to the pixel PX, the first selection transistor TP1 is turned on and the second selection transistor TP2 is turned off, so the first driving current can be provided to the first light emitting element ED1. In this case, the first light emitting element ED1 can provide light at the wide viewing angle, which is the first viewing angle, through the first optical member 161.

In addition, when the high-level first selection signal Ss and the low-level second selection signal Ps are provided to the pixel PX, the first selection transistor TP1 is turned off and the second selection transistor TP2 is turned on, so the second driving current can be provided to the second light emitting element ED2. In this case, the second light emitting element ED2 can provide light at the narrow viewing angle, which is the second viewing angle, through the second optical member 162.

In this way, the selection signal generator SLG to which the first selection signal generation circuit SLC1 is applied can provide the first selection signal Ss and the second selection signal Ps having opposite voltage levels to the pixel PX to control at least one corresponding pixel PX in the first mode or the second mode.

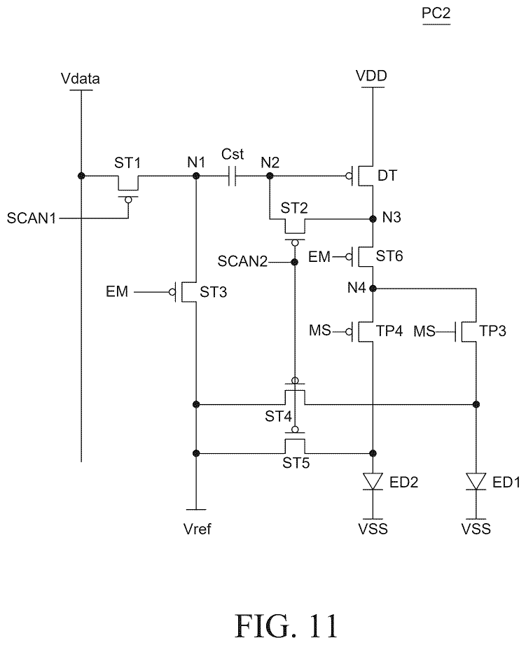

FIG. 11 is a circuit diagram illustrating another example of the pixel circuit included in the display device of FIG. 2.

Meanwhile, the second pixel circuit PC2 illustrated in FIG. 11 represents another example embodiment of pixel circuits corresponding to each of the plurality of pixels PX included in the display device 100 described with reference to FIG. 2. For example, FIG. 11 illustrates a modified example embodiment of the example embodiment of FIG. 4 with respect to the selection transistors TP3 and TP4, and therefore, in FIG. 11, in order to avoid duplicate description, the description will focus on differences from the example embodiment of FIG. 4.

Referring to FIG. 11, the second pixel circuit PC2 can include a driving transistor DT, a plurality of switching transistors ST1 to ST6, a plurality of selection transistors TP3 and TP4, a storage capacitor Cst, and a plurality of light emitting elements ED1 and ED2.

The plurality of selection transistors TP3 and TP4 can include a third selection transistor TP3 configured to generate a current path of a first driving current passing through the first light emitting element ED1 and a fourth selection transistor TP4 configured to generate a current path of a second driving current passing through the second light emitting element ED2.

The third selection transistor TP3 can be connected between the fourth node N4 and the first light emitting element ED1, and the gate electrode of the third selection transistor TP3 can be connected to a selection signal line that provides a selection signal MS.

The fourth selection transistor TP4 can be connected between the fourth node N4 and the second light emitting element ED2, and the gate electrode of the fourth selection transistor TP4 can be connected to the selection signal line that provides the selection signal MS.

The third selection transistor TP3 can be an n-type transistor, and the fourth selection transistor TP4 can be a p-type transistor. Accordingly, when the low-level selection signal MS is supplied to the selection signal line, the third selection transistor TP3 can be turned off and the fourth selection transistor TP4 can be turned on, in response to the low-level selection signal MS. In addition, when the high-level selection signal MS is supplied to the selection signal line, the third selection transistor TP3 can be turned on and the fourth selection transistor TP4 can be turned off, in response to the high-level selection signal MS.

Accordingly, when the pixel PX to which the second pixel circuit PC2 is applied is driven in a first mode which is a share mode, the high-level selection signal MS is supplied to the gate electrode of the third selection transistor TP3 and the gate electrode of the fourth selection transistor TP4, respectively, so the third selection transistor TP3 can be turned on and the fourth selection transistor TP4 can be turned off. Accordingly, the current path of the first driving current passing through the first light emitting element ED1 can be formed, so the first light emitting element ED1 can emit light. Meanwhile, since the second driving current is not generated by the turned-off fourth selection transistor TP4, the second light emitting element ED2 may not emit light.

In addition, when the pixel PX to which the second pixel circuit PC2 is applied is driven in a second mode which is a private mode, the low-level selection signal MS is supplied to the gate electrode of the third selection transistor TP3 and the gate electrode of the fourth selection transistor TP4, respectively, so the third selection transistor TP3 can be turned off and the fourth selection transistor TP4 can be turned on. Accordingly, the current path of the second driving current passing through the second light emitting element ED2 can be formed, so the second light emitting element ED2 can emit light. Meanwhile, since the first driving current is not generated by the turned-off third selection transistor TP3, the first light emitting element ED1 may not emit light.

The first light emitting element ED1 can be connected between the third selection transistor TP3, which is turned on or off by the selection signal MS, and a low-potential power line that provides a low-potential power voltage VSS. The second light emitting element ED2 can be connected between the fourth selection transistor TP4, which is turned on or off by the selection signal MS, and the low-potential power line that provides the low-potential power voltage VSS.

In this case, the first light emitting element ED1 or the second light emitting element ED2 can be connected to other components (e.g., driving transistor DT) of the second pixel circuit PC2 by the third selection transistor TP3 or the fourth selection transistor TP4 turned on according to the driving mode. For example, the first light emitting element ED1 can be connected to the driving transistor DT via the third selection transistor TP3 turned on in the first mode, and can provide light at the wide-viewing angle, which is the first viewing angle, in the first mode (i.e., share mode), by the first driving current. In addition, the second light emitting element ED2 can be connected to the driving transistor DT via the fourth selection transistor TP4 turned on in the second mode, and can provide light at the narrow-viewing angle, which is the second viewing angle, in the second mode (i.e., private mode), by the second driving current. Here, the driving mode can be specified by user input or determined when pre-specified conditions are met.

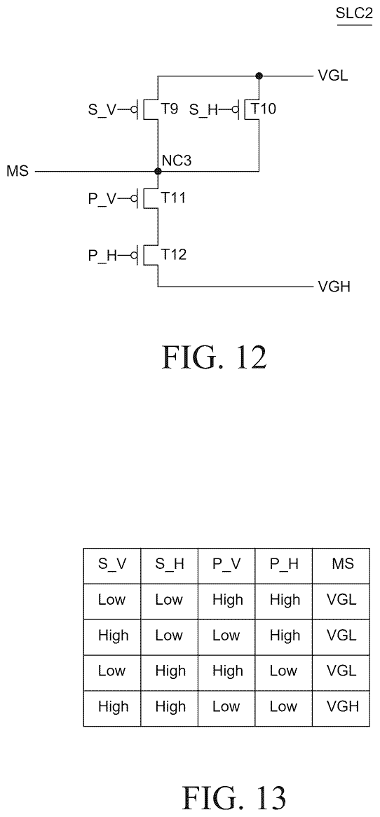

FIG. 12 is a circuit diagram illustrating another example of the selection signal generation circuit included in the display device of FIG. 2.

Meanwhile, the second selection signal generation circuit SLC2 illustrated in FIG. 12 illustrates another example embodiment of the selection signal generation circuit corresponding to each of the plurality of selection signal generators SLG included in the display device 100 described with reference to FIGS. 2 to 3E, and the selection signal generator SLG including the second selection signal generation circuit SLC2 can provide the selection signal to the pixel PX including the second pixel circuit PC2 described with reference to FIG. 11.

Referring to FIG. 12, the plurality of transistors included in the second selection signal generation circuit SLC2 can be n-type transistors or p-type transistors. Hereinafter, for convenience of description, the description will be made on the basis that the plurality of transistors T9 to T12 included in the second selection signal generation circuit SLC2 are p-type transistors. However, at least some of the plurality of transistors T9 to T12 included in the second selection signal generation circuit SLC2 can be modified and implemented as n-type transistors.

The second selection signal generation circuit SLC2 can generate the selection signal MS based on the first to fourth control signals S_V, S_H, P_V, and P_H, the first power voltage VGH, and the second power voltage VGL.

The second selection signal generation circuit SLC2 can control the voltage of the third output node NC3 to the high-level first power voltage VGH or the low-level second power voltage VGL, so the high-level or low-level selection signal MS can be output through the third output node NC3. To this end, the second selection signal generation circuit SLC2 can include ninth to twelfth transistors T9 to T12.

The ninth transistor T9 can be connected between the second power voltage line configured to provide the second power voltage VGL and the third output node NC3. For example, the first electrode of the ninth transistor T9 can be connected to the second power voltage line, and the second electrode of the ninth transistor T9 can be connected to the third output node NC3. The gate electrode of the ninth transistor T9 can be connected to a first control signal line that provides the first control signal S_V. The ninth transistor T9 can be turned on when the turn-on level (e.g., low-level) first control signal S_V is supplied to electrically connect the third output node NC3 and the second power voltage line. In this case, the second power voltage VGL is provided to the third output node NC3, so the second selection signal generation circuit SLC2 can output the low-level selection signal MS.

The tenth transistor T10 can be connected between the second power voltage line configured to provide the second power voltage VGL and the third output node NC3. For example, the first electrode of the tenth transistor T10 can be connected to the second power voltage line, and the second electrode of the tenth transistor T10 can be connected to the third output node NC3. The gate electrode of the tenth transistor T10 can be connected to a second control signal line that provides the second control signal S_H. The tenth transistor T10 can be turned on when the turn-on level (e.g., low-level) second control signal S_H is supplied to electrically connect the third output node NC3 and the second power voltage line. In this case, the second power voltage VGL is provided to the third output node NC3, so the second selection signal generation circuit SLC2 can output the low-level selection signal MS.

The eleventh transistor T11 can be connected between the first power voltage line configured to provide the first power voltage VGH and the third output node NC3. For example, the first electrode of the eleventh transistor T11 can be connected to the twelfth transistor T12, and the second electrode of the eleventh transistor T11 can be connected to the third output node NC3. The gate electrode of the eleventh transistor T11 can be connected to a third control signal line that provides the third control signal P_V. The eleventh transistor T11 can be turned on when the turn-on level (e.g., low-level) third control signal P_V is supplied to electrically connect the third output node NC3 and the twelfth transistor T12.

The twelfth transistor T12 can be connected between the eleventh transistor T11 and the first power voltage line that provides the first power voltage VGH. For example, the first electrode of the twelfth transistor T12 can be connected to the first power voltage line, and the second electrode of the twelfth transistor T12 can be connected to the first electrode of the eleventh transistor T11. The gate electrode of the twelfth transistor T12 can be connected to a fourth control signal line that provides the fourth control signal P_H. The twelfth transistor T12 can be turned on when the turn-on level (e.g., low-level) fourth control signal P_H is supplied to electrically connect the eleventh transistor T11 and the first power voltage line.

The ninth transistor T9 and the tenth transistor T10 can be connected in parallel between the second power voltage line configured to provide the second power voltage VGL and the third output node NC3. Accordingly, when at least one of the ninth transistor T9 and the tenth transistor T10 is turned on, the third output node NC3 and the second power voltage line configured to provide the second power voltage VGL can be electrically connected, so the low-level selection signal MS can be output through the third output node NC3.

In addition, the eleventh transistor T11 and the twelfth transistor T12 can be connected in series between the first power voltage line configured to provide the first power voltage VGH and the third output node NC3. Accordingly, when both the eleventh transistor T11 and the twelfth transistor T12 are turned on, the third output node NC3 and the first power voltage line configured to provide the first power voltage VGH can be electrically connected, so the high-level selection signal MS can be output through the third output node NC3.

In this way, the ninth transistor T9 and the tenth transistor T10 can function as a pull-up unit of the second selection signal generation circuit SLC2, and the eleventh transistor T11 and the twelfth transistor T12 can function as a pull-down unit of the second selection signal generation circuit SLC2. For example, the ninth transistor T9 and the tenth transistor T10 can be defined as a third pull-up unit, and the eleventh transistor T11 and the twelfth transistor T12 can be defined as a third pull-down unit.

FIG. 13 is a diagram for describing an example of the operation of the selection signal generation circuit of FIG. 12.

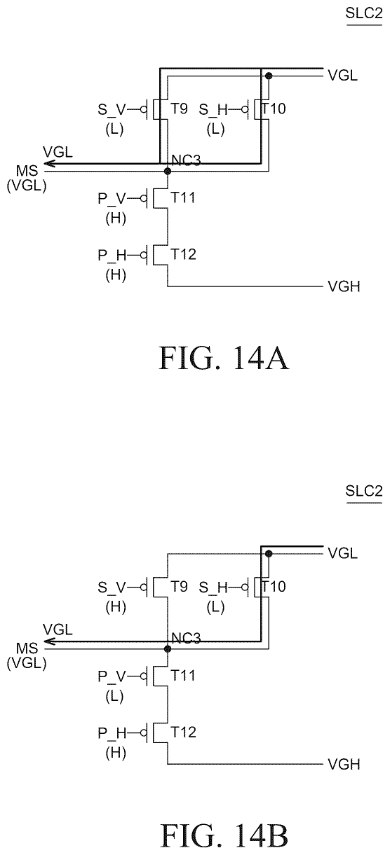

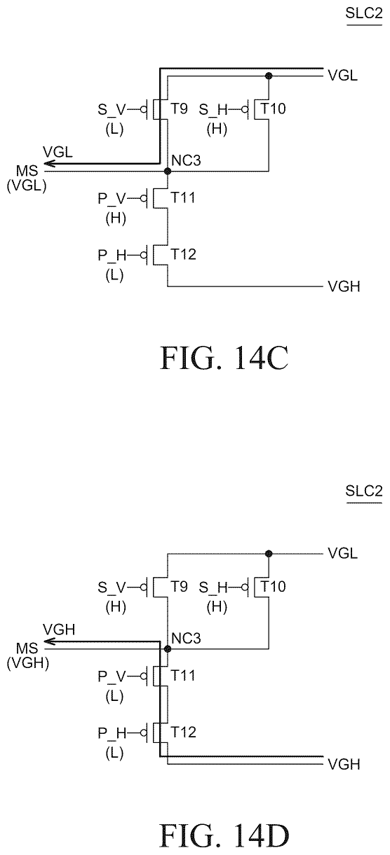

FIGS. 14A to 14D are equivalent circuit diagrams for describing an example of the operation of the selection signal generation circuit of FIG. 12.

Referring to FIGS. 12 and 13, the second selection signal generation circuit SLC2 can output the low-level selection signal MS or the high-level selection signal MS based on the first to fourth control signals S_V, S_H, P_V, and P_H.

For example, further referring to FIG. 14A, when the first control signal S_V and the second control signal S_H are a low level, (i.e., turn-on level), and the third control signal P_V and the fourth control signal P_H are the high level (i.e., turn-off level), the ninth transistor T9 and the tenth transistor T10 can be turned on and the eleventh transistor T11 and the twelfth transistor T12 can be turned off.

In this case, the second power voltage VGL provided from the second power voltage line is provided to the third output node NC3 through the turned-on ninth transistor T9 or the turned-on tenth transistor T10, so the selection signal MS having the low level of the second power voltage VGL can be output.

Next, further referring to FIG. 14B, when the second control signal S_H and the third control signal P_V are a low level, (i.e., turn-on level), and the first control signal S_V and the fourth control signal P_H are the high level (i.e., turn-off level), the tenth transistor T10 and the eleventh transistor T11 can be turned on and the ninth transistor T9 and the twelfth transistor T12 can be turned off.

In this case, the second power voltage VGL provided from the second power voltage line is provided to the third output node NC3 through the turned-on tenth transistor T10, so the selection signal MS having the low level of the second power voltage VGL can be output.

Meanwhile, even if the eleventh transistor T11 is turned on, the twelfth transistor T12 connected in series with the eleventh transistor T11 is turned off, so the first power voltage VGH is not provided to the third output node NC3.

Next, further referring to FIG. 14C, when the second control signal S_H and the third control signal P_V are the high level (i.e., turn-off level), and the first control signal S_V and the fourth control signal P_H are a low level (i.e., a turn-on level), the ninth transistor T9 and the twelfth transistor T12 can be turned on and the tenth transistor T10 and the eleventh transistor T11 can be turned off.

In this case, the second power voltage VGL provided from the second power voltage line is provided to the third output node NC3 through the turned-on ninth transistor T9, so the selection signal MS having the low level of the second power voltage VGL can be output.

Meanwhile, even if the twelfth transistor T12 is turned on, the eleventh transistor T11 connected in series with the twelfth transistor T12 is turned off, so the first power voltage VGH is not provided to the third output node NC3.

Finally, further referring to FIG. 14D, when the first control signal S_V and the second control signal S_H are the high level (i.e., turn-off level), and the third control signal P_V and the fourth control signal P_H are a low level (i.e., turn-on level), the ninth transistor T9 and the tenth transistor T10 can be turned off and the eleventh transistor T11 and the twelfth transistor T12 can be turned on.

In this case, the first power voltage VGH provided from the first power voltage line is provided to the third output node NC3 through the turned-on eleventh transistor T11 and the turned-on twelfth transistor T12 connected in series with each other, so the selection signal MS having the high level of the first power voltage VGH can be output.

In this way, the second selection signal generation circuit SLC2 can provide the selection signal MS having the high level in the first mode to the pixel PX, and provide the selection signal MS having the low level in the second mode to the pixel PX to control the driving mode of the pixel PX.

For example, when the high-level selection signal MS is provided to the pixel PX, the third selection transistor TP3 is turned on and the fourth selection transistor TP4 is turned off, so the first driving current can be supplied to the first light emitting element ED1. In this case, the first light emitting element ED1 can provide light at the wide viewing angle, which is the first viewing angle, through the first optical member 161.

In addition, when the low-level selection signal MS is provided to the pixel PX, the third selection transistor TP3 is turned off and the fourth selection transistor TP4 is turned on, so the second driving current can be provided to the second light emitting element ED2. In this case, the second light emitting element ED2 can provide light at the narrow viewing angle, which is the second viewing angle, through the second optical member 162.

In this way, the selection signal generator SLG to which the second selection signal generation circuit SLC2 is applied provides the selection signal MS having different voltage levels in each mode to the pixel PX, so at least one corresponding pixel PX can be controlled in the first mode or the second mode.

In addition, as described with reference to FIGS. 11 to 14D, by commonly connecting the gate electrodes of the selection transistors TP3 and TP4 included in the pixel circuit of the pixel PX to the same selection signal MS and controlling the voltage level of the selection signal MS according to the driving mode, the number of selection signal lines to control the selection transistors TP3 and TP4 can be reduced and the number of transistors in the selection signal generation circuit of the selection signal generator SLG can be reduced, so the selection signal generation circuit configured to generate the selection signal can be simplified.

FIG. 15 is a circuit diagram illustrating another example of the selection signal generation circuit included in the display device of FIG. 2.

Meanwhile, the third selection signal generation circuit SLC3 illustrated in FIG. 15 illustrates another example embodiment of the selection signal generation circuit corresponding to each of the plurality of selection signal generators SLG included in the display device 100 described with reference to FIGS. 2 to 3E, and the selection signal generator SLG including the third selection signal generation circuit SLC3 can provide the selection signal to the pixel PX including the second pixel circuit PC2 described with reference to FIG. 11.

Referring to FIG. 15, the plurality of transistors included in the third selection signal generation circuit SLC3 can be n-type transistors or p-type transistors. Hereinafter, for convenience of description, the description will be made on the basis that the plurality of transistors T13 to T16 included in the third selection signal generation circuit SLC3 are p-type transistors. However, at least some of the plurality of transistors T13 to T16 included in the third selection signal generation circuit SLC3 can be modified and implemented as n-type transistors.

The third selection signal generation circuit SLC3 can generate the selection signal MS based on the first to fourth control signals S_V, S_H, P_V, and P_H, the first power voltage VGH, and the second power voltage VGL.

The third selection signal generation circuit SLC3 can control the voltage of the fourth output node NC4 to the high-level first power voltage VGH or the low-level second power voltage VGL, so the high-level or low-level selection signal MS can be output through the fourth output node NC4. To this end, the third selection signal generation circuit SLC3 can include thirteenth to sixteenth transistors T13 to T16.

The thirteenth transistor T13 can be connected between the second power voltage line configured to provide the second power voltage VGL and the fourth output node NC4. For example, a first electrode of the thirteenth transistor T13 can be connected to the second power voltage line, and a second electrode of the thirteenth transistor T13 can be connected to the fourteenth transistor T14. A gate electrode of the thirteenth transistor T13 can be connected to a fourth control signal line that provides the fourth control signal P_H. The thirteenth transistor T13 can be turned on when the turn-on level (e.g., low-level) fourth control signal P_H is supplied to electrically connect the second power voltage line and the fourteenth transistor T14.

The fourteenth transistor T14 can be connected between the thirteenth transistor T13 and the fourth output node NC4. For example, a first electrode of the fourteenth transistor T14 can be connected to the second electrode of the thirteenth transistor T13, and a second electrode of the fourteenth transistor T14 can be connected to the fourth output node NC4. A gate electrode of the fourteenth transistor T14 can be connected to a third control signal line that provides the third control signal P_V. The fourteenth transistor T14 can be turned on when the turn-on level (e.g., low-level) third control signal P_V is supplied to electrically connect the thirteenth transistor T13 and the fourth output node NC4.

The fifteenth transistor T15 can be connected between the first power voltage line configured to provide the first power voltage VGH and the fourth output node NC4. For example, a first electrode of the fifteenth transistor T15 can be connected to the first power voltage line, and a second electrode of the fifteenth transistor T15 can be connected to the fourth output node NC4. A gate electrode of the fifteenth transistor T15 can be connected to a first control signal line that provides the first control signal S_V. The fifteenth transistor T15 can be turned on when the turn-on level (e.g., low-level) first control signal S_V is supplied to electrically connect the fourth output node NC4 and the first power voltage line. In this case, the first power voltage VGH is provided to the fourth output node NC4, so the third selection signal generation circuit SLC3 can output the high-level selection signal MS.

The sixteenth transistor T16 can be connected between the first power voltage line configured to provide the first power voltage VGH and the fourth output node NC4. For example, a first electrode of the sixteenth transistor T16 can be connected to the first power voltage line, and a second electrode of the sixteenth transistor T16 can be connected to the fourth output node NC4. A gate electrode of the sixteenth transistor T16 can be connected to a second control signal line that provides the second control signal S_H. The sixteenth transistor T16 can be turned on when the turn-on level (e.g., low-level) second control signal S_H is supplied to electrically connect the fourth output node NC4 and the first power voltage line. In this case, the first power voltage VGH is provided to the fourth output node NC4, so the third selection signal generation circuit SLC3 can output the high-level selection signal MS.

The thirteenth transistor T13 and the fourteenth transistor T14 can be connected in series between the second power voltage line configured to provide the second power voltage VGL and the fourth output node NC4. Accordingly, when both the thirteenth transistor T13 and the fourteenth transistor T14 are turned on, the fourth output node NC4 and the second power voltage line configured to provide the second power voltage VGL can be electrically connected, so the low-level selection signal MS can be output through the fourth output node NC4.

In addition, the fifteenth transistor T15 and the sixteenth transistor T16 can be connected in parallel between the first power voltage line configured to provide the first power voltage VGH and the fourth output node NC4. Accordingly, when at least one of the fifteenth transistor T15 and the sixteenth transistor T16 is turned on, the fourth output node NC4 and the first power voltage line configured to provide the first power voltage VGH can be electrically connected, so the high-level selection signal MS can be output through the fourth output node NC4.

In this way, the thirteenth transistor T13 and the fourteenth transistor T14 can function as a pull-up unit of the third selection signal generation circuit SLC3, and the fifteenth transistor T15 and the sixteenth transistor T16 can function as a pull-down unit of the third selection signal generation circuit SLC3. For example, the thirteenth transistor T13 and the fourteenth transistor T14 can be defined as a fourth pull-up unit, and the fifteenth transistor T15 and sixteenth transistor T16 can be defined as a fourth pull-down unit.

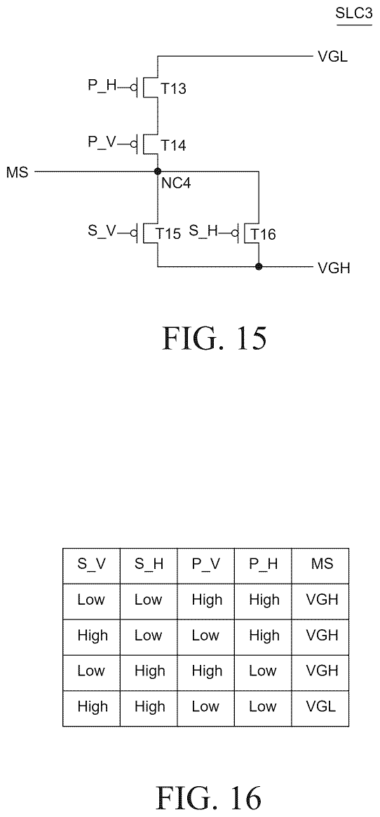

FIG. 16 is a diagram for describing an example of the operation of the selection signal generation circuit of FIG. 15.

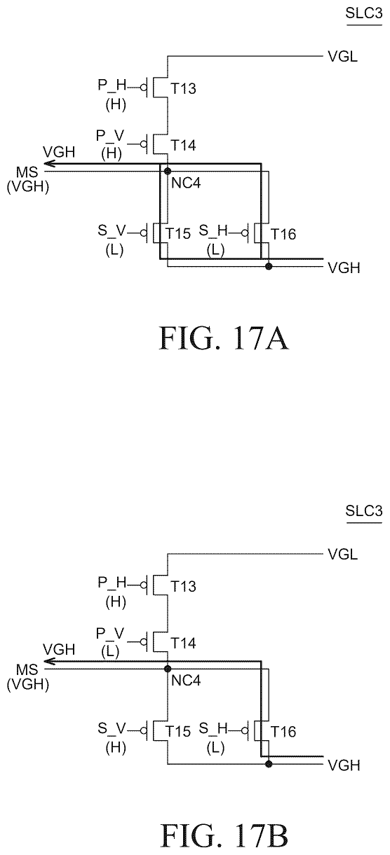

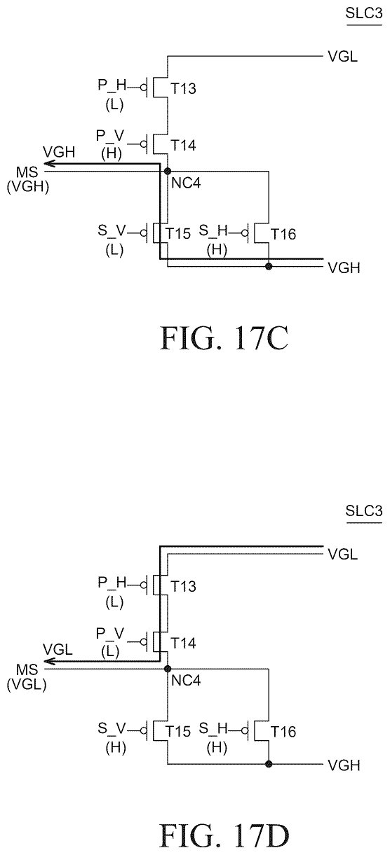

FIGS. 17A to 17D are equivalent circuit diagrams for describing an example of the operation of the selection signal generation circuit of FIG. 15.

Referring to FIGS. 15 and 16, the third selection signal generation circuit SLC3 can output the low-level selection signal MS or the high-level selection signal MS based on the first to fourth control signals S_V, S_H, P_V, and P_H.

For example, further referring to FIG. 17A, when the first control signal S_V and the second control signal S_H are the low level, (i.e., turn-on level), and the third control signal P_V and the fourth control signal P_H are the high level (i.e., turn-off level), the fifteenth transistor T15 and the sixteenth transistor T16 can be turned on and the thirteenth transistor T13 and the fourteenth transistor T14 can be turned off.

In this case, the first power voltage VGH provided from the first power voltage line is provided to the fourth output node NC4 through the turned-on fifteenth transistor T15 and the turned-on sixteenth transistor T16, so the selection signal MS having the high level of the first power voltage VGH can be output.

Next, further referring to FIG. 17B, when the second control signal S_H and the third control signal P_V are the low level (i.e., turn-on level), and the first control signal S_V and the fourth control signal P_H are the high level (i.e., turn-off level), the fourteenth transistor T14 and the sixteenth transistor T16 can be turned on and the thirteenth transistor T13 and the fifteenth transistor T15 can be turned off.

In this case, the first power voltage VGH provided from the first power voltage line is provided to the fourth output node NC4 through the turned-on sixteenth transistor T16, so the selection signal MS having the high level of the first power voltage VGH can be output.

Meanwhile, even if the fourteenth transistor T14 is turned on, the thirteenth transistor T13 connected in series with the fourteenth transistor T14 is turned off, so the second power voltage VGL is not provided to the fourth output node NC4.

Next, further referring to FIG. 17C, when the second control signal S_H and the third control signal P_V are the high level (i.e., turn-off level), and the first control signal S_V and the fourth control signal P_H are the low level (i.e., turn-on level), the fourteenth transistor T14 and the sixteenth transistor T16 can be turned off and the thirteenth transistor T13 and the fifteenth transistor T15 can be turned on.

In this case, the first power voltage VGH provided from the first power voltage line is provided to the fourth output node NC4 through the turned-on fifteenth transistor T15, so the selection signal MS having the high level of the first power voltage VGH can be output.

Meanwhile, even if the thirteenth transistor T13 is turned on, the fourteenth transistor T14 connected in series with the thirteenth transistor T13 is turned off, so the second power voltage VGL is not provided to the fourth output node NC4.

Finally, further referring to FIG. 17D, when the first control signal S_V and the second control signal S_H are the high level (i.e., turn-off level), and the third control signal P_V and the fourth control signal P_H are the low level (i.e., turn-on level), the fifteenth transistor T15 and the sixteenth transistor T16 can be turned off and the thirteenth transistor T13 and the fourteenth transistor T14 can be turned on.

In this case, the second power voltage VGL provided from the second power voltage line is provided to the fourth output node NC4 through the turned-on thirteenth transistor T13 and the turned-on fourteenth transistor T14 connected in series with each other, so the selection signal MS having the low level of the second power voltage VGL can be output.

In this way, the third selection signal generation circuit SLC3 can provide the selection signal MS having the high level in the first mode to the pixel PX, and provide the selection signal MS having the low level in the second mode to the pixel PX to control the driving mode of the pixel PX.

For example, when the high-level selection signal MS is provided to the pixel PX, the third selection transistor TP3 is turned on and the fourth selection transistor TP4 is turned off, so the first driving current can be provided to the first light emitting element ED1. In this case, the first light emitting element ED1 can provide light at the wide viewing angle, which is the first viewing angle, through the first optical member 161.

In addition, when the low-level selection signal MS is provided to the pixel PX, the third selection transistor TP3 is turned off and the fourth selection transistor TP4 is turned on, so the second driving current can be provided to the second light emitting element ED2. In this case, the second light emitting element ED2 can provide light at the narrow viewing angle, which is the second viewing angle, through the second optical member 162.

In this way, the selection signal generator SLG to which the third selection signal generation circuit SLC3 is applied provides the selection signal MS having different voltage levels in each mode to the pixel PX, so at least one corresponding pixel PX can be controlled in the first mode or the second mode.

In addition, as described with reference to FIGS. 11 and FIGS. 15 to 17D, by commonly connecting the gate electrodes of the selection transistors TP3 and TP4 included in the pixel circuit of the pixel PX to the same selection signal MS and controlling the voltage level of the selection signal MS according to the driving mode, the number of selection signal lines to control the selection transistors TP3 and TP4 can be reduced and the number of transistors in the selection signal generation circuit of the selection signal generator SLG can be reduced, so the selection signal generation circuit configured to generate the selection signal can be simplified.

The example embodiments of the present disclosure can also be described as follows:

According to an aspect of the present disclosure, a display device can include: a display panel including an active area and a non-active area surrounding the active area, and including a plurality of pixels and a plurality of selection signal generators disposed on the active area; and a timing controller configured to control the display panel. Each of the plurality of pixels can include a first light emitting element, a first optical member configured to refract light from the first light emitting element, a second light emitting element configured to emit light of the same color as the first light emitting element, and a second optical member configured to refract the light from the second light emitting element and having a different shape from the first optical member. Each of the plurality of selection signal generators can control one of the first light emitting element and the second light emitting element included in at least one corresponding pixel among the plurality of pixels to emit light.

Each of the plurality of pixels can further include a driving transistor configured to generate a first driving current that flows from a high-potential power line configured to provide a high-potential power voltage to a low-potential power line configured to provide a low-potential power voltage through the first light emitting element and a second driving current that flows from the high-potential power line to the low-potential power line through the second light emitting element; a first selection transistor connected between the driving transistor and the first light emitting element, and configured to be turn on in response to a first selection signal supplied to a first selection signal line; and a second selection transistor connected between the driving transistor and the second light emitting element, and configured to be turn on in response to a second selection signal supplied to a second selection signal line.

Each of the plurality of selection signal generators can include a first selection signal output unit configured to output the first selection signal through a first output node based on a first control signal, a second control signal, a third control signal, a fourth control signal, a first power voltage, and a second power voltage; and a second selection signal output unit configured to output the second selection signal through a second output node based on the first control signal, the second control signal, the third control signal, the fourth control signal, the first power voltage, and the second power voltage.

The first selection signal output unit can include a first transistor connected between a second power voltage line that provides the second power voltage and the first output node, and configured to be turn on in response to the first control signal, a second transistor connected between the second power voltage line and the first output node, and configured to be turn on in response to the second control signal, a third transistor connected between the first output node and a first power voltage line that provides the first power voltage, and configured to be turn on in response to the third control signal and a fourth transistor connected between the third transistor and the first power voltage line, and configured to be turn on in response to the fourth control signal.

The first transistor and the second transistor can be connected in parallel between the second power voltage line and the first output node, and the third transistor and the fourth transistor can be connected in series between the first power voltage line and the first output node.

The second selection signal output unit can include a fifth transistor connected between a second power voltage line that provides the second power voltage and the second output node, and configured to be turn on in response to the fourth control signal, a sixth transistor connected between the fifth transistor and the second output node, and configured to be turn on in response to the third control signal, a seventh transistor connected between the second output node and a first power voltage line that provides the first power voltage, and configured to be turn on in response to the first control signal; and an eighth transistor connected between the second output node and the first power voltage line, and configured to be turn on in response to the second control signal.

The fifth transistor and the sixth transistor can be connected in series between the second power voltage line and the second output node, and the seventh transistor and the eighth transistor are connected in parallel between the first power voltage line and the second output node.

Each of the plurality of pixels can further include a driving transistor configured to generate a first driving current that flows from a high-potential power line configured to provide a high-potential power voltage to a low-potential power line configured to provide a low-potential power voltage through the first light emitting element and a second driving current that flows from the high-potential power line to the low-potential power line through the second light emitting element, a third selection transistor connected between the driving transistor and the first light emitting element, and configured to be turn on in response to a selection signal supplied to a selection signal line; and a fourth selection transistor connected between the driving transistor and the second light emitting element, and configured to be turn on in response to the selection signal.

The third selection transistor can be an n-type transistor and the fourth selection transistor is a p-type transistor.

Each of the plurality of selection signal generators outputs the selection signal having a high level or low level based on a first control signal, a second control signal, a third control signal, a fourth control signal, a first power voltage, and a second power voltage.

Each of the plurality of selection signal generators can include a ninth transistor connected between a second power voltage line that provides the second power voltage and a third output node, and configured to be turn on in response to the first control signal; a tenth transistor connected between the second power voltage line and the third output node, and configured to be turn on in response to the second control signal; an eleventh transistor connected between the third output node and a first power voltage line that provides the first power voltage, and configured to be turn on in response to the third control signal; and a twelfth transistor connected between the eleventh transistor and the first power voltage line, and configured to be turn on in response to the fourth control signal.

The ninth transistor and the tenth transistor can be connected in parallel between the second power voltage line and the third output node, and the eleventh transistor and the twelfth transistor can be connected in series between the first power voltage line and the third output node.

Each of the plurality of selection signal generators can include a thirteenth transistor connected between a second power voltage line that provides the second power voltage and a fourth output node, and configured to be turn on in response to the fourth control signal; a fourteenth transistor connected between the thirteenth transistor and the fourth output node, and configured to be turn on in response to the third control signal; a fifteenth transistor connected between the fourth output node and a first power voltage line configured to provide the first power voltage, and configured to be turn on in response to the first control signal; and a sixteenth transistor connected between the fourth output node and the first power voltage line, and configured to be turn on in response to the second control signal.

The thirteenth transistor and the fourteenth transistor can be connected in series between the second power voltage line and the fourth output node, and the fifteenth transistor and the sixteenth transistor are connected in parallel between the first power voltage line and the fourth output node.

The plurality of selection signal generators can control any one of the first light emitting element and the second light emitting element included in one pixel of the plurality of pixels to emit light.

Each of the plurality of selection signal generators can control any one of the first light emitting element and the second light emitting element included in each of at least two pixels of the plurality of pixels to emit light.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including an active area and a non-active area adjacent to the active area, and including a plurality of pixels and a plurality of selection signal generators disposed in the active area; and
a timing controller configured to control the display panel,
wherein each of the plurality of pixels includes:
a first light emitting element;
a first optical member configured to refract light from the first light emitting element;
a second light emitting element configured to emit light of a same color as the first light emitting element; and
a second optical member configured to refract the light from the second light emitting element and having a different shape from the first optical member, and
wherein each of the plurality of selection signal generators controls any one of the first light emitting element and the second light emitting element included in at least one corresponding pixel among the plurality of pixels to emit light.

2. The display device of claim 1,
wherein each of the plurality of pixels further includes:
a driving transistor configured to generate a first driving current that flows from a high-potential power line configured to provide a high-potential power voltage to a low-potential power line configured to provide a low-potential power voltage through the first light emitting element, and a second driving current that flows from the high-potential power line to the low-potential power line through the second light emitting element;
a first selection transistor connected between the driving transistor and the first light emitting element, and configured to be turn on in response to a first selection signal supplied to a first selection signal line; and
a second selection transistor connected between the driving transistor and the second light emitting element, and configured to be turn on in response to a second selection signal supplied to a second selection signal line.

3. The display device of claim 2,
wherein each of the plurality of selection signal generators includes:
a first selection signal output unit configured to output the first selection signal through a first output node based on a first control signal, a second control signal, a third control signal, a fourth control signal, a first power voltage, and a second power voltage; and
a second selection signal output unit configured to output the second selection signal through a second output node based on the first control signal, the second control signal, the third control signal, the fourth control signal, the first power voltage, and the second power voltage.

4. The display device of claim 3,
wherein the first selection signal output unit includes:
a first transistor connected between a second power voltage line that provides the second power voltage and the first output node, and configured to be turn on in response to the first control signal;
a second transistor connected between the second power voltage line and the first output node, and configured to be turn on in response to the second control signal;
a third transistor connected between the first output node and a first power voltage line that provides the first power voltage, and configured to be turn on in response to the third control signal; and
a fourth transistor connected between the third transistor and the first power voltage line, and configured to be turn on in response to the fourth control signal.

5. The display device of claim 4,
wherein the first transistor and the second transistor are connected in parallel between the second power voltage line and the first output node, and
the third transistor and the fourth transistor are connected in series between the first power voltage line and the first output node.

6. The display device of claim 3,
wherein the second selection signal output unit includes:
a fifth transistor connected between a second power voltage line that provides the second power voltage and the second output node, and configured to be turn on in response to the fourth control signal;
a sixth transistor connected between the fifth transistor and the second output node, and configured to be turn on in response to the third control signal;
a seventh transistor connected between the second output node and a first power voltage line that provides the first power voltage and turned on in response to the first control signal; and
an eighth transistor connected between the second output node and the first power voltage line, and configured to be turn on in response to the second control signal.

7. The display device of claim 6,
wherein the fifth transistor and the sixth transistor are connected in series between the second power voltage line and the second output node, and
the seventh transistor and the eighth transistor are connected in parallel between the first power voltage line and the second output node.

8. The display device of claim 1,
wherein each of the plurality of pixels further includes:
a driving transistor configured to generate a first driving current that flows from a high-potential power line configured to provide a high-potential power voltage to a low-potential power line configured to provide a low-potential power voltage through the first light emitting element, and a second driving current that flows from the high-potential power line to the low-potential power line through the second light emitting element;
a third selection transistor connected between the driving transistor and the first light emitting element, and configured to be turn on in response to a selection signal supplied to a selection signal line; and
a fourth selection transistor connected between the driving transistor and the second light emitting element, and configured to be turn on in response to the selection signal.

9. The display device of claim 8,
wherein the third selection transistor is an n-type transistor and the fourth selection transistor is a p-type transistor.

10. The display device of claim 8,
wherein each of the plurality of selection signal generators outputs the selection signal having a high level or low level based on a first control signal, a second control signal, a third control signal, a fourth control signal, a first power voltage, and a second power voltage.

11. The display device of claim 10,
wherein each of the plurality of selection signal generators includes:
a ninth transistor connected between a second power voltage line that provides the second power voltage and a third output node, and configured to be turn on in response to the first control signal;
a tenth transistor connected between the second power voltage line and the third output node, and configured to be turn on in response to the second control signal;
an eleventh transistor connected between the third output node and a first power voltage line that provides the first power voltage, and configured to be turn on in response to the third control signal; and
a twelfth transistor connected between the eleventh transistor and the first power voltage line, and configured to be turn on in response to the fourth control signal.

12. The display device of claim 11,
wherein the ninth transistor and the tenth transistor are connected in parallel between the second power voltage line and the third output node, and
the eleventh transistor and the twelfth transistor are connected in series between the first power voltage line and the third output node.

13. The display device of claim 10,
wherein each of the plurality of selection signal generators includes:
a thirteenth transistor connected between a second power voltage line that provides the second power voltage and a fourth output node, and configured to be turn on in response to the fourth control signal;
a fourteenth transistor connected between the thirteenth transistor and the fourth output node, and configured to be turn on in response to the third control signal;
a fifteenth transistor connected between the fourth output node and a first power voltage line configured to provide the first power voltage, and configured to be turn on in response to the first control signal; and
a sixteenth transistor connected between the fourth output node and the first power voltage line, and configured to be turn on in response to the second control signal.

14. The display device of claim 13,
wherein the thirteenth transistor and the fourteenth transistor are connected in series between the second power voltage line and the fourth output node, and
the fifteenth transistor and the sixteenth transistor are connected in parallel between the first power voltage line and the fourth output node.

15. The display device of claim 1,
wherein each of the plurality of selection signal generators controls any one of the first light emitting element and the second light emitting element included in one pixel of the plurality of pixels to emit light.

16. The display device of claim 1,
wherein each of the plurality of selection signal generators controls any one of the first light emitting element and the second light emitting element included in each of at least two pixels of the plurality of pixels to emit light.

17. The display device of claim 2,
wherein in a first mode, the first light emitting element is connected to the driving transistor via the turned-on first selection transistor and provides light at a first viewing angle by the first driving current, and
wherein in a second mode, the second light emitting element is connected to the driving transistor via the turned-on second selection transistor and provides light at a second viewing angle which is narrower than the first viewing angle, by the second driving current.
